(19) United States
(12) Patent Application Publication
(10) Pub. No.: US 2026/0035778 A1
(43) Pub. Date: Feb. 5, 2026

(54) DEPOSITION MASK, DEPOSITION APPARATUS INCLUDING THE SAME, METHOD OF MANUFACTURING THE SAME, AND ELECTRONIC DEVICE MANUFACTURED BY USING THE SAME

(71) Applicant: Samsung Display Co., LTD., Yongin-si (KR)

(72) Inventors: Jeong Kuk KIM, Yongin-si (KR); Duck Jung LEE, Yongin-si (KR); Yeon Woo LEE, Yongin-si (KR); Ji Hyun JUNG, Yongin-si (KR); Jun Ho JO, Yongin-si (KR)

(73) Assignee: Samsung Display Co., LTD., Yongin-si (KR)

(21) Appl. No.: 19/059,981

(22) Filed: Feb. 21, 2025

(30) Foreign Application Priority Data
Aug. 1, 2024 (KR) 10-2024-0102292

(51) Int. Cl. C23C 14/04; C23C 14/30; H10K 59/12; H10K 71/16

(52) U.S. Cl. CPC C23C 14/042; C23C 14/30; H10K 59/1201; H10K 71/166

(57) ABSTRACT

Provided are a deposition mask, a deposition apparatus including the same, a method of manufacturing the same, and an electronic device manufactured by using the same. The deposition mask includes a mask frame having cell openings and including a rib region defining the cell openings, a membrane including mask cell regions each disposed on the cell openings, and reflective patterns disposed on inner surfaces of the cell openings and reflecting thermal radiation energy.

### CROSS-REFERENCE TO RELATED APPLICATION(S)

This application claims priority to and benefits of Korean Patent Application No. 10-2024-0102292 under 35 U.S.C. 119, filed on Aug. 1, 2024, in the Korean Intellectual Property Office (KIPO), the entire contents of which are incorporated herein by reference.

### BACKGROUND

### 1. Technical Field

The disclosure relates to a deposition mask, a deposition apparatus including the same, a method of manufacturing the same, and an electronic device manufactured by using the same.

### 2. Description of the Related Art

Wearable devices in which a focus is formed at a distance close to user's eyes have been developed in the form of glasses or a helmet. For example, the wearable device may be a head mounted display (HMD) device or AR glasses. The wearable device may provide an augmented reality (hereinafter, referred to as “AR”) screen or a virtual reality (hereinafter, referred to as “VR”) screen to a user.

In the case of wearable devices such as the HMD device or the AR glasses, a display specification of approximately 3000 PPI (pixels per inch) or higher is required to allow users to use them for a long time without symptoms of dizziness. To this end, organic light emitting diode on silicon (OLEDoS) technology used in high-resolution small-sized organic light emitting display devices is emerging. The OLEDOS is a technology in which organic light emitting diodes (OLEDs) are disposed on a semiconductor wafer on which complementary metal oxide semiconductor (CMOS) elements are disposed.

In order to manufacture a display panel with a high resolution of about 3000 PPI or higher, a high-resolution deposition mask is required. For example, the deposition mask may be manufactured by forming a membrane having multiple pixel openings on a substrate such as a silicon wafer, and partially removing the substrate to form cell openings that expose the pixel openings.

A deposition mask may be used in a deposition process for forming light emitting layers on a backplane substrate. While the deposition process is being performed, the backplane substrate may be disposed on the deposition mask, and a deposition source may be disposed under the deposition mask. The deposition source may heat and evaporate an organic material for forming the light emitting layers, and the evaporated organic material may be deposited on the backplane substrate through the deposition mask.

The deposition mask may be heated by thermal radiation energy radiated from the deposition source, which may cause thermal deformation of the deposition mask. Further, the thermal deformation of the deposition mask may cause a problem that the pixel position accuracy (PPA) of the light emitting layers deteriorates.

### SUMMARY

Aspects and features of embodiments of the disclosure provide an improved deposition mask capable of reducing thermal deformation, a deposition apparatus including the same, a method of manufacturing the same, and an electronic device manufactured by using the same.

However, embodiments of the disclosure are not limited to those set forth herein. The above and other embodiments of the disclosure will become more apparent to one of ordinary skill in the art to which the disclosure pertains by referencing the detailed description of the disclosure given below.

According to an embodiment of the disclosure, a deposition mask may include a mask frame having cell openings and including a rib region defining the cell openings, a membrane including mask cell regions each disposed on the cell openings, and reflective patterns disposed on inner surfaces of the cell openings and reflecting thermal radiation energy.

The reflective patterns may be made of a metal or a metal oxide.

The reflective patterns may include at least one of aluminum (Al), titanium (Ti), magnesium (Mg), zinc (Zn), cerium (Ce), tantalum (Ta), tungsten (W), molybdenum (Mo), chromium (Cr), nickel (Ni), ruthenium (Ru), palladium (Pd), platinum (Pt), gold (Au), silver (Ag), and copper (Cu).

The reflective patterns may include at least one of aluminum oxide (Al2O3), titanium oxide (TiO2), magnesium oxide (MgO), zinc oxide (ZnO), and cerium oxide (CeO2).

Each of the inner surfaces of the cell openings may have an inclination such that the cell openings have a width that gradually decreases toward the membrane.

The reflective patterns may have a thickness in a range of about 10 nm to about 100 nm.

The deposition mask may further include a reflective layer. The membrane may be disposed on a front surface of the mask frame, the reflective layer may be disposed on a rear surface of the mask frame, and the reflective layer and the reflective patterns may be made of a same material.

According to an embodiment of the disclosure, a deposition apparatus may include a deposition source, a deposition mask disposed above the deposition source, and a substrate chuck supporting the substrate such that the substrate faces the deposition mask. In such case, the deposition mask may include a mask frame having cell openings and including a rib region defining the cell openings, a membrane including mask cell regions each disposed on the cell openings, and reflective patterns disposed on inner surfaces of the cell openings and reflecting thermal radiation energy.

The reflective patterns may be made of a metal or a metal oxide.

Each of the inner surfaces of the cell openings may have an inclination such that the cell openings have a width that gradually decreases toward the membrane.

The deposition mask may further include a reflective layer. The membrane may be disposed on a front surface of the mask frame, the reflective layer may be disposed on a rear surface of the mask frame, and the reflective layer and the reflective patterns may be made of a same material.

The deposition apparatus may further include a mask stage which is disposed above the deposition source and on which the deposition mask is placed.

The mask stage may include a lattice support supporting the rib region of the mask frame, and a mask chuck having a ring shape surrounding the lattice support in a plan view and supporting an edge portion of the mask frame.

The lattice support and the reflective patterns may be made of a same material.

The mask stage may further include a coating layer disposed on the lattice support, and the coating layer and the reflective patterns may be made of a same material.

According to an embodiment of the disclosure, a method of manufacturing a deposition mask may include forming an inorganic layer on a substrate, patterning the inorganic layer to form mask cell regions each having a plurality of pixel openings exposing the substrate, patterning the substrate to form cell openings each exposing the mask cell regions, and forming reflective patterns made of a material reflecting thermal radiation energy on inner surfaces of the cell openings.

The reflective patterns may be made of a metal or a metal oxide.

The substrate may be a single crystal silicon substrate, and the cell openings may be formed by a wet etching process to have a width that gradually decreases toward the inorganic layer.

The reflective patterns may be formed by an electron beam evaporation process using a shadow mask that exposes the inner surfaces of the cell openings.

The method may further include forming a reflective layer on a rear surface of the substrate. The inorganic layer may be formed on a front surface of the substrate. The reflective layer and the reflective patterns may be made of a same material and formed simultancously.

According to an embodiment of the disclosure, an electronic device may include a display panel comprising a substrate and light emitting layers formed on the substrate using a deposition mask. The deposition mask may include a mask frame having cell openings and comprising a rib region defining the cell openings, a membrane comprising mask cell regions each disposed on the cell openings, and reflective patterns disposed on inner surfaces of the cell openings and reflecting thermal radiation energy.

According to the embodiments, reflective patterns capable of reflecting thermal radiation energy may be arranged on the inner surfaces of cell openings of a mask frame, so that thermal radiation energy radiated from a deposition source may be reflected by the reflective patterns. As a result, thermal deformation of the deposition mask due to the thermal radiation energy radiated from the deposition source may be reduced.

Other features and embodiments may be apparent from the following detailed description and the drawings.

### BRIEF DESCRIPTION OF THE DRAWINGS

The above and other aspects and features of the disclosure will become more apparent by describing in detail embodiments thereof with reference to the attached drawings, in which:

FIG. 1 is a schematic block diagram of an electronic device according to one embodiment of the disclosure;

FIG. 2 is a schematic diagram of an electronic device according to various embodiments of the disclosure;

FIG. 3 is an exploded perspective view illustrating a display device according to one embodiment of the disclosure;

FIG. 4 is a schematic block diagram for explaining the display device shown in FIG. 3;

FIG. 5 is a schematic diagram of an equivalent circuit of a first sub-pixel shown in FIG. 4 according to an embodiment;

FIG. 6 is a schematic plan view illustrating an embodiment of the display panel shown in FIG. 3;

FIG. 7 is a schematic plan view illustrating an embodiment of the display area shown in FIG. 6;

FIG. 8 is a schematic plan view illustrating another embodiment of the display area shown in FIG. 6;

FIG. 9 is a schematic cross-sectional view illustrating an embodiment of the display panel taken along line I-I′ of FIG. 7;

FIG. 10 is a schematic perspective view illustrating an embodiment of a head mounted display;

FIG. 11 is a schematic exploded perspective view illustrating the head mounted display shown in FIG. 10;

FIG. 12 is a schematic perspective view illustrating another embodiment of a head mounted display;

FIG. 13 is a schematic cross-sectional view illustrating a deposition mask and a deposition apparatus including the same according to an embodiment of the disclosure;

FIG. 14 is a schematic bottom view illustrating a backplane substrate as shown in FIG. 13;

FIG. 15 is a schematic plan view illustrating a deposition mask as shown in FIG. 13;

FIG. 16 is a schematic enlarged plan view illustrating mask cell regions as shown in FIG. 15;

FIG. 17 is a schematic cross-sectional view taken along line II-II′ as shown in FIG. 16;

FIG. 18 is a schematic cross-sectional view illustrating a method of forming reflective patterns as shown in FIG. 17;

FIG. 19 is a schematic cross-sectional view illustrating another embodiment of the deposition mask as shown in FIG. 17;

FIG. 20 is a schematic cross-sectional view illustrating a mask stage as shown in FIG. 13;

FIG. 21 is a schematic enlarged cross-sectional view illustrating a lattice support as shown in FIG. 20;

FIG. 22 is a schematic enlarged cross-sectional view illustrating another embodiment of the lattice support as shown in FIG. 20; and

FIGS. 23 to 29 are schematic cross-sectional views illustrating a method of manufacturing a deposition mask according to an embodiment of the disclosure.

### DETAILED DESCRIPTION OF THE EMBODIMENTS

Advantages and features of the disclosure and methods of accomplishing the same may be understood more readily by reference to the following detailed description of embodiments and the accompanying drawings. The disclosure may, however, be embodied in many different forms and should not be construed as being limited to the embodiments set forth herein. Rather, these embodiments are provided so that this disclosure will be more thorough and complete and will fully convey the concept of the disclosure to those skilled in the art, and the disclosure will only be defined by the appended claims.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another clement. The same reference numbers indicate the same components throughout the specification.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

Although the terms first, second, etc. may be used herein to describe various components, these components should not be limited by these terms. These terms are used to distinguish one component from another component. Thus, a first component discussed below could be termed a second component without departing from the teachings of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Each of the features of the various embodiments of the disclosure may be combined or combined with each other, in part or in whole, and technically various interlocking and driving are possible. Each embodiment may be implemented independently of each other or may be implemented together in an association.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described in detail with reference to the accompanying drawings.

The display device according to one embodiment of the disclosure may be applied to various electronic devices. The electronic device according to the one embodiment of the disclosure may include the display device described above, and may further include modules or devices having additional functions in addition to the display device.

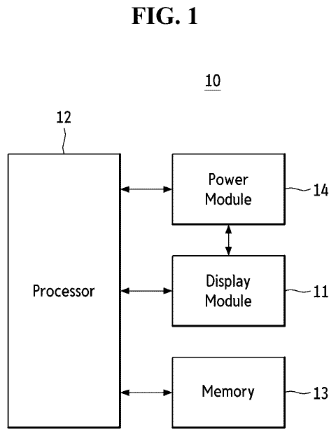

FIG. 1 is a schematic block diagram of an electronic device according to one embodiment of the disclosure.

Referring to FIG. 1, the electronic device 10 according to one embodiment of the disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information for the operation of the processor 12 or the display module 11. In case that the processor 12 executes an application stored in the memory 13, an image data signal and/or an input control signal may be transmitted to the display module 11, and the display module 11 may process the received signal and output image information through a display screen.

The power module 14 may include a power supply module such as, for example, a power adapter or a battery, and a power conversion module that converts the power supplied by the power supply module to generate power for the operation of the electronic device 10.

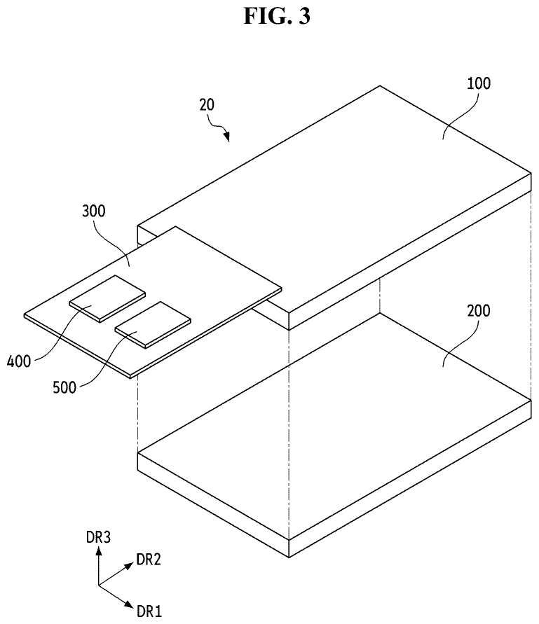

At least one of the components of the electronic device 10 according to the one embodiment of the disclosure may be included in the display device 20 (see FIG. 3) according to the embodiments of the disclosure. In an embodiment, some of the individual modules functionally included in the electronic device 10 may be included in the display device 20, and another one of the individual modules may be provided separately from the display device 20. For example, the display device 20 may include the display module 11, and the processor 12, the memory 13, and the power module 14 may be provided in a form of other devices in the electronic device 10 other than the display device 20.

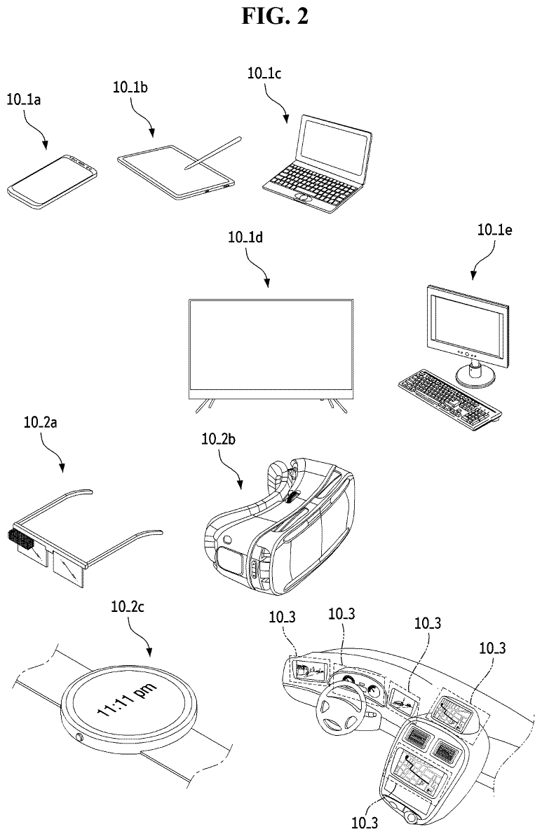

FIG. 2 is a schematic diagram of an electronic device according to various embodiments of the disclosure.

Referring to FIG. 2, various electronic devices to which electronic devices 10 according to embodiments of the disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.t

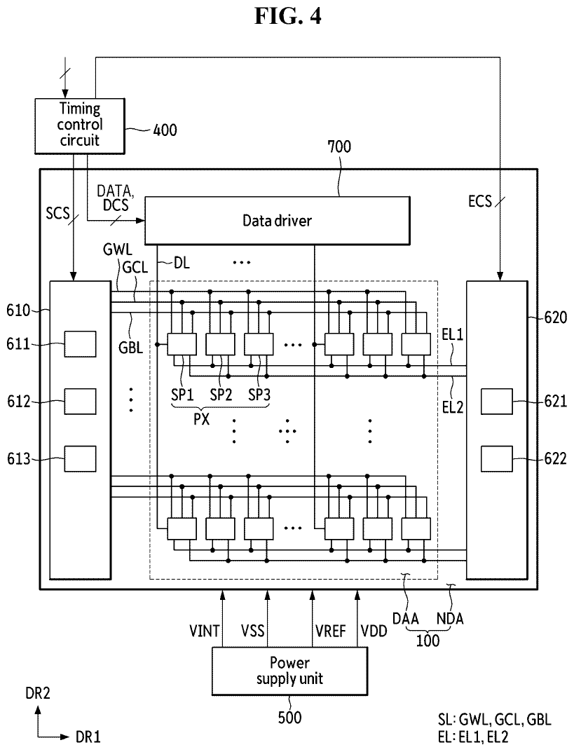

FIG. 3 is an exploded perspective view illustrating a display device according to one embodiment of the disclosure. FIG. 4 is a schematic block diagram for explaining the display device shown in FIG. 3.

Referring to FIGS. 3 and 4, a display device 20 may be a device displaying a moving image or a still image. The display device 20 may be applied to portable electronic devices such as a mobile phone, a smartphone, a tablet personal computer (PC), a mobile communication terminal, an electronic organizer, an electronic book, a portable multimedia player (PMP), a navigation system, an ultra mobile PC (UMPC), and the like. For example, the display device 20 may be applied as a display module of electronic devices such as a television, a laptop, a monitor, a billboard, an Internet-of-Things (IoT) device, and the like. For example, the display device 20 may be applied to electronic devices such as a smart watch, a watch phone, a head mounted display (HMD) for implementing virtual reality and augmented reality, and the like.

The display device 20 may include a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side in a first direction DR1 and a long side in a second direction DR2 intersecting the first direction DR1. In the display panel 100, a corner where a short side in the first direction DR1 and a long side in the second direction DR2 meet may be right-angled or rounded with a curvature. The planar shape of the display panel 100 is not limited to a quadrilateral shape, and may be a shape similar to another polygonal shape, a circular shape, or an elliptical shape. The planar shape of the display device 20 may conform to the planar shape of the display panel 100, but the disclosure is not limited thereto.

The display panel 100 may include multiple pixels PX, multiple scan lines SL, multiple emission control lines EL, multiple data lines DL, a scan driver 610, an emission driver 620, and a data driver 700. As shown in FIG. 4, the display panel 100 may be divided into a display area DAA displaying an image and a non-display area NDA not displaying an image.

The pixels PX may be disposed in the display area DAA. The pixels PX may be arranged in a matrix form along the first direction DR1 and the second direction DR2. The scan lines SL and the emission control lines EL may extend in the first direction DR1 and arranged in the second direction DR2. The data lines DL may extend in the second direction DR2 and arranged in the first direction DR1.

The scan lines SL may include multiple write scan lines GWL, multiple control scan lines GCL, and multiple bias scan lines GBL. The emission control lines EL may include multiple first emission control lines EL1 and multiple second emission control lines EL2.

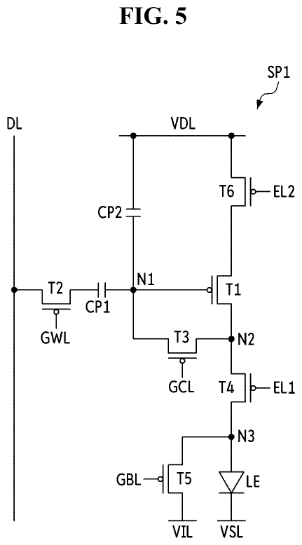

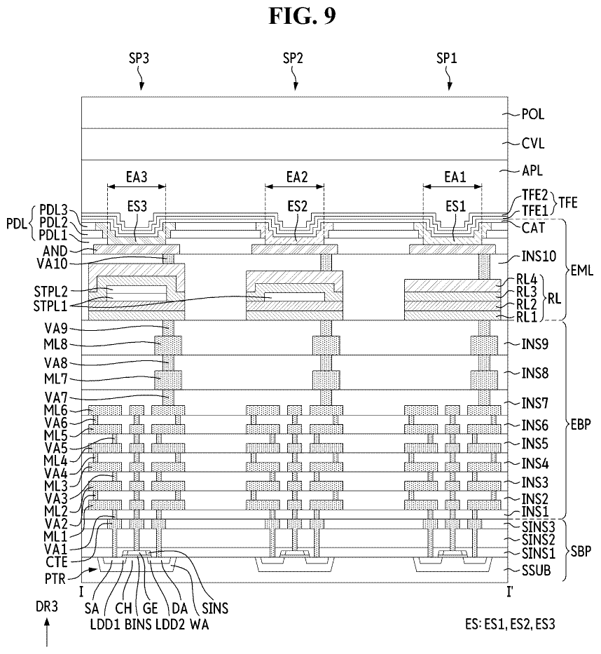

The pixels PX may include multiple sub-pixels SP1, SP2, and SP3. The sub-pixels SP1, SP2, and SP3 may include multiple pixel transistors (see FIG. 5). The pixel transistors may be formed by a semiconductor process, and may be disposed on a semiconductor substrate SSUB (see FIG. 9). For example, the pixel transistors of the data driver 700 may be formed through a complementary metal oxide semiconductor (CMOS) process, but the disclosure is not limited thereto.

Each of the sub-pixels SP1, SP2, and SP3 may be connected to one of the write scan lines GWL, one of the control scan lines GCL, one of the bias scan lines GBL, one of the first emission control lines EL1, one of the second emission control lines EL2, and one of the data lines DL. Each of the sub-pixels SP1, SP2, and SP3 may receive a data voltage from the data line DL in response to a write scan signal of the write scan line GWL, and emit light from the light-emitting element according to the data voltage.

The scan driver 610, the emission driver 620, and the data driver 700 may be disposed in the non-display area NDA.

The scan driver 610 may include multiple scan transistors, and the emission driver 620 may include multiple light-emitting transistors. The scan transistors and the light-emitting transistors may be formed on the semiconductor substrate SSUB (see FIG. 9) through a semiconductor process. For example, the scan transistors and the light-emitting transistors may be formed through a CMOS process, but the disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output the write scan signals sequentially to the write scan lines GWL. The control scan signal output unit 612 may generate control scan signals in response to the scan timing control signal SCS and sequentially output the control scan signals to the control scan lines GCL. The bias scan signal output unit 613 may generate bias scan signals according to the scan timing control signal SCS and output the bias scan signals sequentially to bias scan lines GBL.

The emission driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include multiple data transistors, and the data transistors may be formed through a semiconductor process, and formed on the semiconductor substrate SSUB (see FIG. 9). For example, the data transistors may be formed through a CMOS process, but the disclosure is not limited thereto.

The data driver 700 may receive digital video data DATA and a data timing control signal DCS from the timing control circuit 400. The data driver 700 may convert the digital video data DATA into analog data voltages according to the data timing control signal DCS and output the analog data voltages to the data lines DL. The sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on a surface of the display panel 100, for example, on the rear surface of the display panel 100. The heat dissipation layer 200 may serve to dissipate heat generated from the display panel 100. The heat dissipation layer 200 may include a material having high thermal conductivity, such as graphite, or a metal layer such as silver (Ag), copper (Cu), or aluminum (Al).

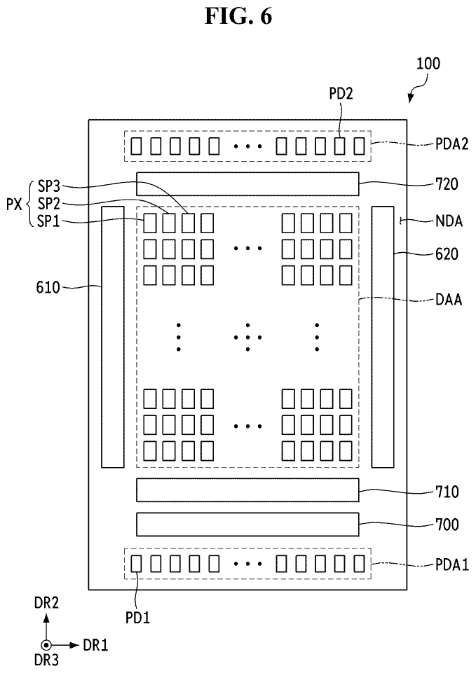

The circuit board 300 may be electrically connected to multiple first pads PD1 (see FIG. 6) of a first pad portion PDA1 (see FIG. 6) of the display panel 100 by using a conductive adhesive member such as an anisotropic conductive film. The circuit board 300 may be a flexible printed circuit board with a flexible material, or a flexible film. Although the circuit board 300 is illustrated in FIG. 3 as being unfolded, the circuit board 300 may be bendable. An end of the circuit board 300 may be disposed on the rear surface of the display panel 100 and/or the rear surface of the heat dissipation layer 200. Another end of the circuit board 300 may be connected to the first pads PD1 (see FIG. 6) of the first pad portion PDA1 (see FIG. 6) of the display panel 100 by using a conductive adhesive member. The end of the circuit board 300 may be an opposite end of the another end of the circuit board 300.

The timing control circuit 400 may receive digital video data and timing signals input from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data DATA and the data timing control signal DCS to the data driver 700.

The power supply circuit 500 may generate multiple panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described below in conjunction with FIG. 5.

Each of the timing control circuit 400 and the power supply circuit 500 may be formed as an integrated circuit (IC) and attached to a surface of the circuit board 300. The scan timing control signal SCS, the emission timing control signal ECS, digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

For example, each of the timing control circuit 400 and the power supply circuit 500 may be disposed in the non-display area NDA of the display panel 100, similarly to the scan driver 610, the emission driver 620, and the data driver 700. The timing control circuit 400 may include multiple timing transistors, and each power supply circuit 500 may include multiple power transistors. The timing transistors and the power transistors may be formed through a semiconductor process, and formed on the semiconductor substrate SSUB (see FIG. 9). For example, the timing transistors and the power transistors may be formed through a CMOS process, but the disclosure is not limited thereto. Each of the timing control circuit 400 and the power supply circuit 500 may be disposed between the data driver 700 and the first pad portion PDA1 (see FIG. 6).

FIG. 5 is a schematic diagram of an equivalent circuit of a first sub-pixel shown in FIG. 4 according to an embodiment.

Referring to FIG. 5, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. The first driving voltage VSS may be lower than the third driving voltage VINT. The second driving voltage VDD may be higher than the third driving voltage VINT.

The first sub-pixel SP1 may include multiple transistors T1 to T6, a light-emitting clement LE, a first capacitor CP1, and a second capacitor CP2.

The light-emitting element LE may emit light in response to a driving current flowing through the channel of the first transistor T1. The emission amount of the light-emitting clement LE may be proportional to the driving current. The light-emitting element LE may be disposed between a fourth transistor T4 and the first driving voltage line VSL. The first electrode of the light-emitting element LE may be connected to the drain electrode of the fourth transistor T4, and the second electrode of the light-emitting element LE may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but the disclosure is not limited thereto. In another embodiment, the light-emitting element LE may be an inorganic light-emitting element including a first electrode, a second electrode, and an inorganic semiconductor disposed between the first electrode and the second electrode, in which case the light-emitting element LE may be a micro light-emitting diode.

The first transistor T1 may be a driving transistor that controls a source-drain current (hereinafter also referred to as “driving current”) flowing between the source electrode and the drain electrode of the first transistor T1 according to a voltage applied to the gate electrode of the first transistor T1. The first transistor T1 may include a gate electrode connected to a first node N1, a source electrode connected to the drain electrode of a sixth transistor T6, and a drain electrode connected to a second node N2.

A second transistor T2 may be disposed between an electrode of the first capacitor CP1 and the data line DL. The second transistor T2 may be turned on by the write scan signal of the write scan line GWL to connect the electrode of the first capacitor CP1 to the data line DL. Accordingly, the data voltage of the data line DL may be applied to the electrode of the first capacitor CP1. The second transistor T2 may include a gate electrode connected to the write scan line GWL, a source electrode connected to the data line DL, and a drain electrode connected to the electrode of the first capacitor CP1.

A third transistor T3 may be disposed between the first node N1 and the second node N2. The third transistor T3 may be turned on by the control scan signal of the control scan line GCL to connect the first node N1 to the second node N2. In case that the gate electrode and the source electrode of the first transistor T1 are connected, the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 may be turned on by the first emission control signal of the first emission control line EL1 to connect the second node N2 to the third node N3. Accordingly, the driving current of the first transistor T1 may be supplied to the light-emitting element LE. The fourth transistor T4 may include a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 may be turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 may be turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be disposed between the first node Nl and the drain electrode of the second transistor T2. The first capacitor CP1 may include an electrode connected to the drain electrode of the second transistor T2 and another electrode connected to the first node N1.

The second capacitor CP2 may be formed between the gate electrode of the first transistor T1 and the second driving voltage line VDL. The second capacitor CP2 may include an electrode connected to the gate electrode of the first transistor T1 and another electrode connected to the second driving voltage line VDL.

The first node N1 may be a junction between the gate electrode of the first transistor T1, the drain electrode of the third transistor T3, the another electrode of the first capacitor CP1, and the electrode of the second capacitor CP2. The second node N2 may be a junction between the drain electrode of the first transistor T1, the source electrode of the third transistor T3, and the source electrode of the fourth transistor T4. The third node N3 may be a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the disclosure is not limited thereto. In another embodiment, each of the first to sixth transistors T1 to T6 may be an N-type MOSFET. In another embodiment, some of the first to sixth transistors T1 to T6 may be P-type MOSFETs, and each of the remaining transistors may be an N-type MOSFET.

Although it is illustrated in FIG. 5 that the first sub-pixel SP1 includes six transistors T1 to T6 and two capacitors C1 and C2, it should be noted that the first sub-pixel SP1 is not limited to that shown in FIG. 5. For example, the number of transistors and the number of capacitors of the first sub-pixel SP1 are not limited to those shown in FIG. 5.

Further, the first sub-pixel SP1 described in conjunction with FIG. 5, the second sub-pixel SP2, and the third sub-pixel SP3 may have a substantially same circuit configuration. Therefore, the description of the second sub-pixel SP2 and the third sub-pixel SP3 will be omitted in the disclosure.

FIG. 6 is a schematic plan view illustrating an embodiment of the display panel shown in FIG. 3.

Referring to FIG. 6, the display area DAA of the display panel 100 may include multiple pixels PX arranged in a matrix form. The non-display area NDA of the display panel 100 may include the scan driver 610, the emission driver 620, the data driver 700, a first distribution circuit 710, a second distribution circuit 720, the first pad portion PDA1, and a second pad portion PDA2.

The scan driver 610 may be disposed on a first side of the display area DAA, and the emission driver 620 may be disposed on a second side of the display area DAA. For example, the scan driver 610 may be disposed on a side of the display area DAA in the first direction DR1, and the emission driver 620 may be disposed on another side of the display area DAA in the first direction DR1. For example, as shown in FIG. 6, the scan driver 610 may be disposed on the left side of the display area DAA, and the emission driver 620 may be disposed on the right side of the display area DAA. However, the disclosure is not limited thereto, and the scan driver 610 and the emission driver 620 may be disposed on both the first side and the second side of the display area DAA.

The first pad portion PDA1 may include the first pads PD1 connected to pads or bumps of the circuit board 300 through a conductive adhesive member. The first pad portion PDA1 may be disposed on a third side of the display area DAA. For example, the first pad portion PDA1 may be disposed on a side of the display area DAA in the second direction DR2. The first pad portion PDA1 may be disposed outside the data driver 700 in the second direction DR2. For example, as shown in FIG. 6, the first pad portion PDA1 may be disposed closer to the edge of the display panel 100 than the data driver 700.

The second pad portion PDA2 may include multiple second pads PD2 corresponding to inspection pads that test whether the display panel 100 operates normally. The second pads PD2 may be connected to a jig or probe pins during an inspection process, or may be connected to a circuit board for inspection. The circuit board for inspection may be a printed circuit board made of a rigid material or a flexible printed circuit board made of a flexible material.

The second pad portion PDA2 may be disposed on a fourth side of the display area DAA. For example, the second pad portion PDA2 may be disposed on another side of the display area DAA in the second direction DR2. The second pad portion PDA2 may be disposed outside the second distribution circuit 720 in the second direction DR2. For example, as shown in FIG. 6, the second pad portion PDA2 may be disposed closer to the edge of the display panel 100 than the second distribution circuit 720.

The first distribution circuit 710 may distribute data voltages applied through the first pad portion PDA1 to the data lines DL. For example, the first distribution circuit 710 may distribute the data voltages applied through a first pad PD1 of the first pad portion PDA1 to the P (P is a positive integer of 2 or more) data lines DL, and as a result, the number of the first pads PD1 may be reduced. The first distribution circuit 710 may be disposed on the third side of the display area DAA of the display panel 100. For example, the first distribution circuit 710 may be disposed on a side of the display area DAA in the second direction DR2. For example, as shown in FIG. 6, the first distribution circuit 710 may be disposed on the lower side of the display area DAA.

The second distribution circuit 720 may distribute signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on another side of the display area DAA in the second direction DR2. For example, as shown in FIG. 6, the second distribution circuit 720 may be disposed on the upper side of the display area DAA.

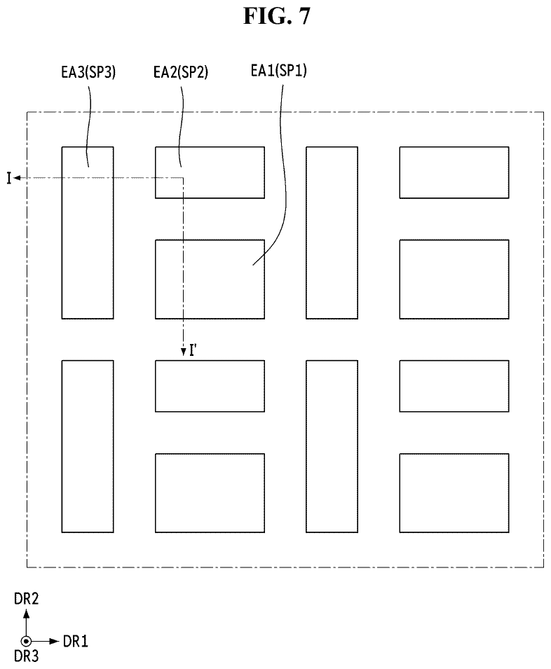

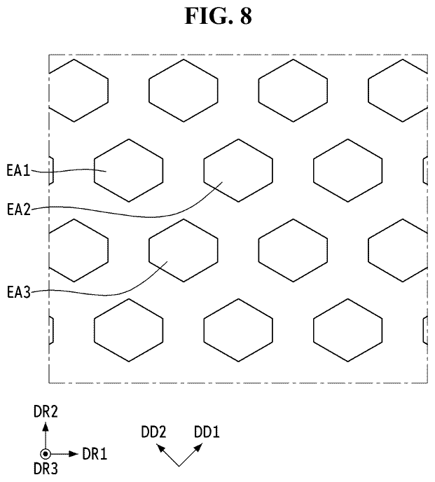

FIG. 7 is a schematic plan view illustrating an embodiment of the display area shown in FIG. 6. FIG. 8 is a schematic plan view illustrating another embodiment of the display area shown in FIG. 6.

Referring to FIG. 7, each of the pixels PX may include a first sub-pixel SP1, a second sub-pixel SP2, and a third sub-pixel SP3. The first to third sub-pixels SP1, SP2, and SP3 may include emission arcas EA1, EA2, and EA3, respectively. For example, the first sub-pixel SP1 may include the first emission area EA1, the second sub-pixel SP2 may include the second emission area EA2, and the third sub-pixel SP3 may include the third emission area EA3.

Each of the first emission area EA1, the second emission area EA2, and the third emission area EA3 may be an area defined by a pixel defining film PDL (see FIG. 9). For example, each of the first emission area EA1, the second emission area EA2, and the third emission area EA3 may be an area defined by a first pixel defining film PDL1 (see FIG. 9).

The length of the third emission area EA3 in the first direction DR1 may be less than the length of the first emission area EA1 in the first direction DR1 and the length of the second emission area EA2 in the first direction DR1. The length of the first emission area EA1 in the first direction DR1 and the length of the second emission area EA2 in the first direction DR1 may be substantially the same.

The length of the third emission area EA3 in the second direction DR2 may be greater than the length of the first emission area EA1 in the second direction DR2 and the length of the second emission area EA2 in the second direction DR2. The length of the first emission area EA1 in the second direction DR2 may be greater than the length of the second emission area EA2 in the second direction DR2.

In each of the pixels PX, the first emission area EA1 and the second emission area EA2 may be adjacent to each other in the second direction DR2. Further, the first emission area EA1 and the third emission area EA3 may be adjacent to each other in the first direction DR1. Further, the second emission area EA2 and the third emission area EA3 may be adjacent to each other in the first direction DR1. The area of the first emission area EA1, the area of the second emission area EA2, and the area of the third emission area EA3 may be different from each other.

The first emission area EA1 may emit light of a first color, the second emission area EA2 may emit light of a second color, and the third emission area EA3 may emit light of a third color. In an embodiment, the light of the first color may be light of a red wavelength band, the light of the second color may be light of a green wavelength band, and the light of the third color may be light of a blue wavelength band. For example, the blue wavelength band may be a wavelength band of light having a main peak wavelength in a range of about 370 nm to about 460 nm, the green wavelength band may be a wavelength band of light having a main peak wavelength in a range of about 480 nm to about 560 nm, and the red wavelength band may be a wavelength band of light having a main peak wavelength in a range of about 600 nm to about 750 nm.

In another embodiment, as shown in FIG. 8, the first emission area EA1, the second emission area EA2, and the third emission area EA3 may be disposed in a hexagonal structure having a hexagonal shape in a plan view. The first emission area EA1 and the second emission area EA2 may be adjacent to each other in the first direction DR1, the second emission area EA2 and the third emission area EA3 may be adjacent to each other in a first diagonal direction DD1, and the first emission area EA1 and the third emission area EA3 may be adjacent to each other in a second diagonal direction DD2.

Although it is illustrated in FIGS. 7 and 8 that each of the pixels PX includes three emission areas EA1, EA2, and EA3, the disclosure is not limited thereto. In another embodiment, each of the pixels PX may include four emission areas. In another embodiment, each of the emission areas EA1, EA2, and EA3 may have a polygonal, circular, elliptical, or atypical shape in a plan view, unlike those shown in FIGS. 7 and 8.

The arrangement of the emission areas EA1, EA2, and EA3 of the pixels PX is not limited to the embodiments illustrated in FIGS. 7 and 8. For example, the emission areas of the pixels PX may be arranged in a stripe structure in which the emission areas are arranged in the first direction DR1, a PenTile® structure in which the emission areas are arranged in a diamond shape, or the like.

FIG. 9 is a schematic cross-sectional view illustrating an embodiment of the display panel taken along line I-I′ of FIG. 7.

Referring to FIG. 9, the display panel 100 may include a semiconductor backplane SBP, a light-emitting element backplane EBP, a display element layer EML, an encapsulation layer TFE, an adhesive layer APL, a cover layer CVL, and a polarizing plate POL.

The semiconductor backplane SBP may include the semiconductor substrate SSUB including multiple pixel transistors PTR, multiple semiconductor insulating films covering the pixel transistors PTR, and multiple contact terminals CTE electrically connected to the pixel transistors PTR, respectively. The pixel transistors PTR may be the first to sixth transistors T1 to T6 described with reference to FIG. 5.

The semiconductor substrate SSUB may be a silicon substrate, a germanium substrate, or a silicon-germanium substrate. The semiconductor substrate SSUB may be a substrate doped with a first type impurity. Multiple well regions WA may be disposed at top surface portions of the semiconductor substrate SSUB. The well regions WA may be regions doped with a second type impurity. The second type impurity and the first type impurity may be different from each other. For example, in case that the first type impurity is a p-type impurity, the second type impurity may be an n-type impurity. For example, in case that the first type impurity is an n-type impurity, the second type impurity may be a p-type impurity.

Each of the well regions WA may include a source region SA corresponding to the source electrode of the pixel transistor PTR, a drain region DA corresponding to the drain electrode of the pixel transistor PTR, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on a side of the gate electrode GE, and the drain region DA may be disposed on another side of the gate electrode GE.

Each of the well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having an impurity concentration lower than an impurity concentration of the source region SA. The second low-concentration impurity region LDD2 may be a region having an impurity concentration lower than an impurity concentration of the drain region DA. A distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that may be caused by a short channel may be reduced or prevented.

A first semiconductor insulating film SINS1 may be disposed on the semiconductor substrate SSUB. The first semiconductor insulating film SINS1 may be formed of silicon carbonitride (SiCN) or a silicon oxide (SiOₓ)-based inorganic film, but the disclosure is not limited thereto.

A second semiconductor insulating film SINS2 may be disposed on the first semiconductor insulating film SINS1. The second semiconductor insulating film SINS2 may be formed of a silicon oxide (SiOₓ)-based inorganic film, but the disclosure is not limited thereto.

The contact terminals CTE may be disposed on the second semiconductor insulating film SINS2. Each of the contact terminals CTE may be connected to one of the gate electrode GE, the source region SA, and the drain region DA of each of the pixel transistors PTR through contact plugs penetrating the first semiconductor insulating film SINS1 and the second semiconductor insulating film INS2. The contact terminals CTE may be formed of at least one of copper (Cu), aluminum (Al), tungsten (W), molybdenum (Mo), chromium (Cr), gold (Au), titanium (Ti), nickel (Ni), neodymium (Nd), and an alloy thereof.

A third semiconductor insulating film SINS3 may be disposed on side surfaces of the contact terminals CTE. The top surface of each of the contact terminals CTE may be exposed without being covered by the third semiconductor insulating film SINS3. The third semiconductor insulating film SINS3 may be formed of a silicon oxide (SiOₓ)-based inorganic film, but the disclosure is not limited thereto.

The semiconductor substrate SSUB may be replaced with a glass substrate or a polymer resin substrate including a material such as polyimide. Thin film transistors may be disposed on the glass substrate or the polymer resin substrate. The glass substrate may be a rigid substrate that does not bend, and the polymer resin substrate may be a flexible substrate that can be bent or curved.

The light-emitting element backplane EBP may include multiple conductive layers ML1 to ML8, multiple vias VA1 to VA9, and multiple insulating films INS1 to INS9. The insulating films INS1 to INS9 may be used for electrical insulation between the conductive layers ML1 to ML8.

The first to eighth conductive layers ML1 to ML8 may be connected to the contact terminals CTE exposed from the semiconductor backplane SBP, and serve to implement the circuit of the first sub-pixel SP1 shown in FIG. 5. For example, the first to sixth transistors T1 to T6 may be formed in the semiconductor backplane SBP, and the connection of the first to sixth transistors T1 to T6 and the first and second capacitors C1 and C2 may be implemented by the first to eighth conductive layers ML1 to ML8. In an embodiment, the connection between the drain region corresponding to the drain electrode of the fourth transistor T4, the source region corresponding to the source electrode of the fifth transistor T5, and a first electrode AND of the light-emitting clement LE (see FIG. 5) may be implemented by the first to eighth conductive layers ML1 to ML8.

The first insulating film INS1 may be disposed on the semiconductor backplane SBP. Each of the first vias VA1 may penetrate the first insulating film INS1 and be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate the second insulating film INS2 and be connected to the first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate the third insulating film INS3 and be connected to the second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate the fourth insulating film INS4 and be connected to the third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate the fifth insulating film INS5 and be connected to the fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate the sixth insulating film INS6 and be connected to the fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate the seventh insulating film INS7 and be connected to the sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate the eighth insulating film INS8 and be connected to the seventh conductive layer ML7. Each of the eighth conductive layers ML8 may be disposed on the eighth insulating film INS8 and may be connected to the eighth via VA8.

The first to eighth conductive layers ML1 to ML8 may be made of substantially a same material. For example, the first to eighth conductive layers ML1 to ML8 may be formed of at least one of copper (Cu), aluminum (Al), tungsten (W), molybdenum (Mo), chromium (Cr), gold (Au), titanium (Ti), nickel (Ni), neodymium (Nd), and an alloy thereof. The first to eighth vias VA1 to VA8 may be made of substantially a same material. For example, the first to eighth vias VA1 to VA8 may be formed of at least one of copper (Cu), aluminum (Al), tungsten (W), molybdenum (Mo), chromium (Cr), gold (Au), titanium (Ti), nickel (Ni), neodymium (Nd), and an alloy thereof. First to eighth insulating films INS1 to INS8 may be formed of a silicon oxide (SiOₓ)-based inorganic film, but the disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. For example, the thickness of each of the second conductive layer ML2, the third conductive layer ML3, the fourth conductive layer ML4, the fifth conductive layer ML5, and the sixth conductive layer ML6 may be approximately 1440 Å. For example, the thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9,000 Å. For example, the thickness of each of the seventh via VA7 and the eighth via VA8 may be approximately 6,000 Å.

A ninth insulating film INS9 may be disposed on the eighth insulating film INS8 and the eighth conductive layer ML8. The ninth insulating film INS9 may be formed of a silicon oxide (SiOₓ)-based inorganic film, but the disclosure is not limited thereto.

Each of the ninth vias VA9 may penetrate the ninth insulating film INS9 and be connected to the eighth conductive layer ML8. The ninth vias VA9 may be formed of at least one of copper (Cu), aluminum (Al), tungsten (W), molybdenum (Mo), chromium (Cr), gold (Au), titanium (Ti), nickel (Ni), neodymium (Nd), and an alloy thereof. For example, the thickness of the ninth via VA9 may be approximately 16,500 Å.

The display element layer EML may be disposed on the light-emitting element backplane EBP. The display element layer EML may include a reflective electrode layer RL, a tenth insulating film INS10, a tenth via VA10, light-emitting elements LE, and a pixel defining film PDL. Each of the light-emitting elements LE may include a first electrode AND, a light-emitting stack ES, and a second electrode CAT.

The reflective electrode layer RL may be disposed on the ninth insulating film INS9. The reflective electrode layer RL may include at least one reflective electrode RL1, RL2, RL3, and RL4, a first step layer STPL1, and a second step layer STPL2. In an embodiment, the reflective electrode layer RL may include first to fourth reflective electrodes RL1, RL2, RL3, and RL4 as shown in FIG. 9.

Each of the first reflective electrodes RL1 may be disposed on the ninth insulating film INS9, and may be connected to the ninth via VA9. The first reflective electrodes RL1 may be formed of at least one of copper (Cu), aluminum (Al), tungsten (W), molybdenum (Mo), chromium (Cr), gold (Au), titanium (Ti), nickel (Ni), neodymium (Nd), and an alloy thereof. For example, the first reflective electrodes RLI may include titanium nitride (TiN).

Each of the second reflective electrodes RL2 may be disposed on the first reflective electrode RL1. The second reflective electrodes RL2 may be formed of at least one of copper (Cu), aluminum (Al), tungsten (W), molybdenum (Mo), chromium (Cr), gold (Au), titanium (Ti), nickel (Ni), neodymium (Nd), and an alloy thereof. For example, the second reflective electrodes RL2 may include aluminum (Al).

The first step layer STPL1 may be disposed on the second reflective electrode RL2 in the second sub-pixel SP2 and the third sub-pixel SP3. The first step layer STPL1 may not be disposed on the second reflective electrode RL2 in the first sub-pixel SP1.

The second step layer STPL2 may be disposed on the first step layer STPL1 in the third sub-pixel SP3. The second step layer STPL2 may not be disposed on the second reflective electrode RL2 in the first sub-pixel SP1. The second step layer STPL2 may not be disposed on the first step layer STPL1 in the second sub-pixel SP2.

The thickness of the first step layer STPL1 may be set in consideration of the wavelength of the light of the second color and a distance from the light-emitting stack ES of the second sub-pixel SP2 to the fourth reflective electrode RL4 to advantageously reflect the light of the second color emitted from the light-emitting stack ES. The thickness of the second step layer STPL2 may be set in consideration of the wavelength of the light of the third color and a distance from the light-emitting stack ES of the third sub-pixel SP3 to the fourth reflective electrode RLA to advantageously reflect the light of the third color emitted from the light-emitting stack ES.

The first step layer STPL1 and the second step layer STPL2 may be formed of silicon carbonitride (SiCN) or a silicon oxide (SiOₓ)-based inorganic film, but the disclosure is not limited thereto.

In the first sub-pixel SP1, the third reflective electrode RL3 may be disposed on the second reflective electrode RL2. In the second sub-pixel SP2, the third reflective electrode RL3 may be disposed on the first step layer STPL1 and the second reflective electrode RL2. In the third sub-pixel SP3, the third reflective electrode RL3 may be disposed on the second step layer STPL2 and the second reflective electrode RL2. The third reflective electrodes RL3 may be formed of at least one of copper (Cu), aluminum (Al), tungsten (W), molybdenum (Mo), chromium (Cr), gold (Au), titanium (Ti), nickel (Ni), neodymium (Nd), and an alloy thereof. For example, the third reflective electrodes RL3 may include titanium nitride (TiN).

In an embodiment, at least one of the first reflective electrode RL1, the second reflective electrode RL2, and the third reflective electrode RL3 may be omitted.

Each of the fourth reflective electrodes RL4 may be disposed on the third reflective electrode RL3. The fourth reflective electrodes RL4 may be a layer that reflects light from the light-emitting stack ES. The fourth reflective electrodes RL4 may include a metal having high reflectivity to advantageously reflect the light. Since the fourth reflective electrode RL4 is an electrode that substantially reflects light from the light-emitting elements LE, the thickness of the fourth reflective electrode RL4 may be greater than the thickness of each of the first reflective electrode RL1, the second reflective electrode RL2, and the third reflective electrode RL3. The fourth reflective electrodes RL4 may be formed of at least one of copper (Cu), aluminum (Al), tungsten (W), molybdenum (Mo), chromium (Cr), gold (Au), titanium (Ti), nickel (Ni), neodymium (Nd), and an alloy including any one of them. For example, the fourth reflective electrodes RL4 may include aluminum (Al) or titanium (Ti).

The tenth insulating film INS10 may be disposed on the ninth insulating film INS9 and the fourth reflective electrodes RL4. The tenth insulating film INS10 may be an optical auxiliary layer through which light reflected by the reflective electrode layer RL passes, among light emitted from the light-emitting elements LE. The tenth insulating film INS10 may be formed of a silicon oxide (SiOₓ)-based inorganic film, but the disclosure is not limited thereto.

Each of the tenth vias VA10 may penetrate the tenth insulating film VA10 and be connected to the reflective electrode layer RL. The tenth vias VA10 may be formed of at least one of copper (Cu), aluminum (Al), tungsten (W), molybdenum (Mo), chromium (Cr), gold (Au), titanium (Ti), nickel (Ni), neodymium (Nd), and an alloy thereof.

The thicknesses of the tenth vias VA10 may be different in the first sub-pixel SP1, the second sub-pixel SP2, and the third sub-pixel SP3 in order to adjust a resonance distance of light emitted from the light-emitting elements LE in at least one of the first sub-pixel SP1, the second sub-pixel SP2, or the third sub-pixel SP3. For example, the thickness of the tenth via VA10 in the third sub-pixel SP3 may be less than the thickness of the tenth via VA10 in each of the first sub-pixel SP1 and the second sub-pixel SP2. Further, the thickness of the tenth via VA10 in the second sub-pixel SP2 may be less than the thickness of the tenth via VA10 in the first sub-pixel SP1. For example, the distance between the light-emitting stack ES and the reflective electrode layer RL may be different in the first sub-pixel SP1, the second sub-pixel SP2, and the third sub-pixel SP3.

In summary, in order to adjust the distance between the light-emitting stack ES and the reflective electrode layer RL according to the main wavelength of light emitted from the first sub-pixel SP1, the second sub-pixel SP2, and the third sub-pixel SP3, the presence or absence of the first and second step layers STPL1 and STPL2 and the thickness of each of the first and second step layers STPL1 and STPL2 in the first sub-pixel SP1, the second sub-pixel SP2, and the third sub-pixel SP3 may be set.

The first electrode AND of each of the light-emitting elements LE may be disposed on the tenth insulating film INS10 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be formed of at least one of copper (Cu), aluminum (Al), tungsten (W), molybdenum (Mo), chromium (Cr), gold (Au), titanium (Ti), nickel (Ni), neodymium (Nd), and an alloy thereof. For example, the first electrode AND of each of the light-emitting elements LE may include titanium nitride (TiN).

The pixel defining film PDL may be disposed on the tenth insulating film INS10 and a part of the first electrode AND of each of the light-emitting elements LE. The pixel defining film PDL may cover an edge of the first electrode AND of each of the light-emitting elements LE. The pixel defining film PDL may serve to partition the first emission areas EA1, the second emission areas EA2, and the third emission areas EA3. For example, the pixel defining film PDL may have openings that partially expose the first electrode AND of each of the light-emitting elements LE in a plan view.

The first emission area EA1 may be defined as an area in which the first electrode AND, the light-emitting stack ES, and the second electrode CAT are sequentially stacked in the first sub-pixel SP1 to emit light. The second emission area EA2 may be defined as an area in which the first electrode AND, the light-emitting stack ES, and the second electrode CAT are sequentially stacked in the second sub-pixel SP2 to emit light. The third emission area EA3 may be defined as an area in which the first electrode AND, the light-emitting stack ES, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the tenth insulating film INS10 and the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOₓ)-based inorganic film, but the disclosure is not limited thereto. The first pixel defining film PDL1, the second pixel defining film PDL2, and the third pixel defining film PDL3 may each have a thickness of about 500 Å.

In case that the first pixel defining film PDL1, the second pixel defining film PDL2, and the third pixel defining film PDL3 are formed as one pixel defining film, the height of one pixel defining film may increase, so that a first encapsulation inorganic film TFE1 may be cut off due to step coverage. Step coverage may be a ratio of the degree of thin film coated on an inclined portion to the degree of thin film coated on a flat portion. The lower the step coverage, the more likely it is that the thin film may be cut off at inclined portions.

Therefore, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the widths of the openings of the first pixel defining film PDL1 may be less than the widths of the openings of the second pixel defining film PDL2, and the widths of the openings of the second pixel defining film PDL2 may be less than the widths of the openings of the third pixel defining film PDL3.

The light-emitting stack ES may include a first light-emitting stack ESI disposed in the first emission area EA1, a second light-emitting stack ES2 disposed in the second emission area EA2, and a third light-emitting stack ES3 disposed in the third emission area EA3. Although not shown in detail, the first light-emitting stack ES may include a hole injecting layer, a hole transporting layer, a first light-emitting layer, an electron transporting layer, and an electron injecting layer, the second light-emitting stack ES2 may include the hole injecting layer, the hole transporting layer, a second light-emitting layer, the electron transporting layer, and the electron injecting layer, and the third light-emitting stack ES3 may include the hole injecting layer, the hole transporting layer, a third light-emitting layer, the electron transporting layer, and the electron injecting layer.

For example, the hole injecting layer may be disposed on the first electrodes AND exposed by the openings of the pixel defining film PDL, the inner surfaces of the openings of the pixel defining film PDL, and the top surface of the pixel defining film PDL. The hole transporting layer may be disposed on the hole injecting layer.

The first to third light-emitting layers may be respectively disposed in the openings of the pixel defining film PDL on the hole transporting layer. The first light-emitting layer may be disposed in the opening of the pixel defining film PDL in the first emission area EA1, and may emit light of a first color, for example, red light. The second light-emitting layer may be disposed in the opening of the pixel defining film PDL in the second emission area EA2, and may emit light of a second color, for example, green light. The third light-emitting layer may be disposed in the opening of the pixel defining film PDL in the third emission area EA3, and may emit light of a third color, for example, blue light.

The electron transporting layer may be disposed on the first to third light-emitting layers and the hole transporting layer, and the electron injecting layer may be disposed on the electron transporting layer.

In another embodiment, although not shown, multiple trenches (not shown) may be disposed between the first to third emission areas EA1, EA2, and EA3. The trenches may have a ring shape respectively surrounding the first to third emission areas EA1, EA2, and EA3 in a plan view, and may penetrate the pixel defining film PDL. The hole injecting layer and the hole transporting layer formed on the first electrodes AND of the first to third emission areas EA1, EA2, and EA3 may be disconnected from each other by the trenches.

In another embodiment, the first to third light-emitting stacks ES1, ES2, and ES3 may be respectively disposed in the openings of the pixel defining film PDL, and may not be disposed on the pixel defining film PDL. The first to third light-emitting stacks ES1, ES2, and ES3 may be disconnected from each other by the pixel defining film PDL.

The second electrode CAT may be disposed on the first to third light-emitting stacks ES1, ES2, and ES3. The second electrode CAT may be formed of a transparent conductive material (TCO) such as ITO or IZO that can transmit light or a semi-transmissive conductive material such as magnesium (Mg), silver (Ag), or an alloy of Mg and Ag. In case that the second electrode CAT is formed of a semi-transmissive conductive material, the light emission efficiency may be improved in each of the first to third sub-pixels SP1, SP2, and SP3 by forming a micro-cavity.

The encapsulation layer TFE may be disposed on the display element layer EML. The encapsulation layer TFE may include at least one inorganic film TFE1 and TFE2 to reduce or prevent oxygen or moisture from permeating into the display element layer EML. For example, the encapsulation layer TFE may include the first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films including at least one of silicon nitride (SiNₓ), silicon oxynitride (SiON), and silicon oxide (SiOₓ) are alternately stacked each other. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOₓ) or aluminum oxide (AlOₓ), but the disclosure is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

The adhesive layer APL may increase the interfacial adhesion between the encapsulation layer TFE and the cover layer CVL. The adhesive layer APL may be an organic film including at least one of an acrylic resin, an epoxy resin, a phenolic resin, a polyamide resin, and a polyimide resin.

The cover layer CVL may be disposed on the adhesive layer APL. The cover layer CVL may be a glass substrate or a polymer resin substrate. In case that the cover layer CVL is a glass substrate, the cover layer CVL may be attached onto the adhesive layer APL, and may serve as an encapsulation substrate. In case that the cover layer CVL is formed of a polymer resin, the cover layer CVL may be directly applied onto the adhesive layer APL.

The polarizing plate POL may be disposed on the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but the disclosure is not limited thereto.

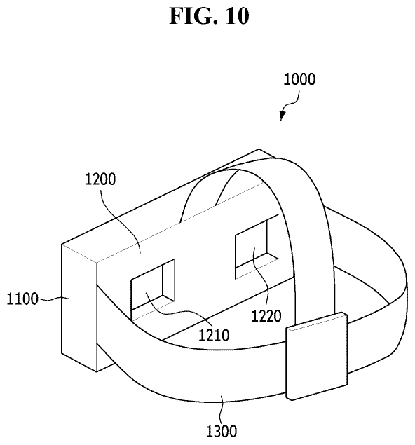

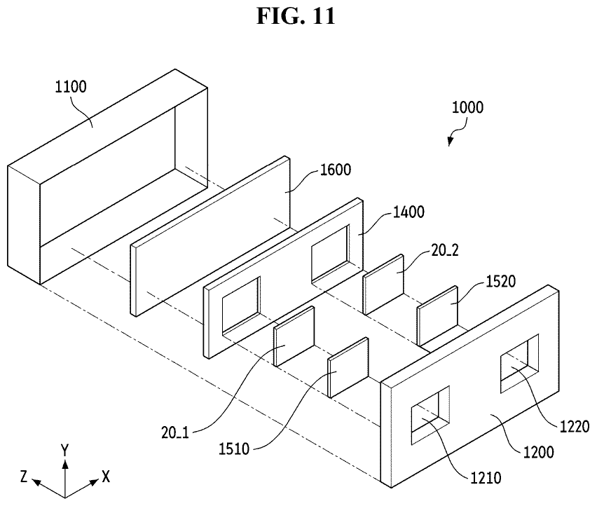

FIG. 10 is a schematic perspective view illustrating a head mounted display. FIG. 11 is a schematic exploded perspective view illustrating an embodiment of the head mounted display shown in FIG. 10.

Referring to FIGS. 10 and 11, a head mounted display 1000 according to one embodiment may include a first display device 20_1, a second display device 20_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 20_1 may provide an image to the user's left eye, and the second display device 20_2 may provide an image to the user's right eye. Since each of the first display device 20_1, the second display device 20_2, and the display device 20 described in conjunction with FIGS. 3 and 4 are substantially the same, description of the first display device 20_1 and the second display device 20_2 will be omitted.

The first optical member 1510 may be disposed between the first display device 20_1 and the first eyepiece 1210. The second optical member 1520 may be disposed between the second display device 20_2 and the second eyepiece 1220. Each of the first optical member 1510 and the second optical member 1520 may include at least one convex lens.

The middle frame 1400 may be disposed between the first and second display devices 20_1 and 20_2 and the control circuit board 1600. The middle frame 1400 may support and fix the first display device 20_1, the second display device 20_2, and the control circuit board 1600.

The control circuit board 1600 may be disposed between the middle frame 1400 and the display device housing 1100. The control circuit board 1600 may be connected to the first display device 20_1 and the second display device 20_2 through a connector. The control circuit board 1600 may convert an image source input from the outside into the digital video data DATA, and transmit the digital video data DATA to the first display device 20_1 and the second display device 20_2 through a connector.

The control circuit board 1600 may transmit the digital video data DATA corresponding to a left-eye image optimized for the user's left eye to the first display device 20_1, and may transmit the digital video data DATA corresponding to a right-eye image optimized for the user's right eye to the second display device 20_2. In another embodiment, the control circuit board 1600 may transmit a same digital video data DATA to the first display device 20_1 and the second display device 20_2.

The display device housing 1100 may accommodate the first display device 20_1, the second display device 20_2, the middle frame 1400, the first optical member 1510, the second optical member 1520, and the control circuit board 1600. The housing cover 1200 may cover an open surface of the display device housing 1100. The housing cover 1200 may include the first eyepiece 1210 at which the user's left eye is located and the second eyepiece 1220 at which the user's right eye is located. FIGS. 10 and 11 schematically illustrate that the first eyepiece 1210 and the second eyepiece 1220 are disposed separately, but the disclosure is not limited thereto. In another embodiment, the first eyepiece 1210 and the second eyepiece 1220 may be combined into one.

The first eyepiece 1210 may be aligned with the first display device 20_1 and the first optical member 1510, and the second eyepiece 1220 may be aligned with the second display device 20_2 and the second optical member 1520. Therefore, the user may view, through the first eyepiece 1210, the image of the first display device 20_1 magnified as a virtual image by the first optical member 1510, and may view, through the second eyepiece 1220, the image of the second display device 20_2 magnified as a virtual image by the second optical member 1520.

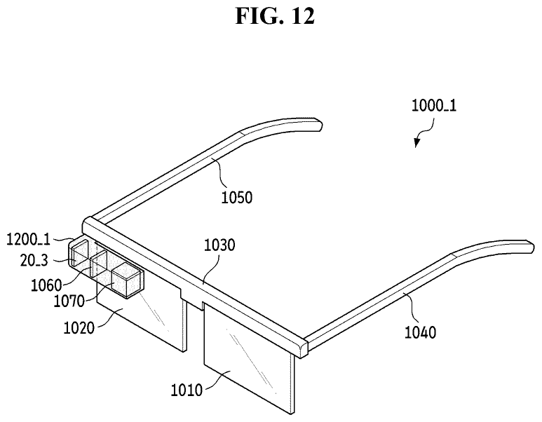

The head mounted band 1300 may secure the display device housing 1100 to the user's head such that the first eyepiece 1210 and the second eyepiece 1220 of the housing cover 1200 remain located on the user's left and right eyes, respectively. In case that the display device housing 1100 is implemented to be lightweight and compact, the head mounted display 1000 may be provided in a form of glasses as shown in FIG. 12.

In an embodiment, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 12 is a schematic perspective view illustrating another embodiment of a head mounted display.

Referring to FIG. 12, a head mounted display 1000_1 may be an eyeglasses-type display device in which a display device housing 1200_1 is implemented in a lightweight and compact manner. The head mounted display 1000_1 may include a display device 20_3, a left eye lens 1010, a right eye lens 1020, a support frame 1030, temples 1040 and 1050, an optical member 1060, an optical path conversion member 1070, and the display device housing 1200_1.

The display device housing 1200_1 may house the display device 20_3, the optical member 1060, and the optical path conversion member 1070. The image displayed on the display device 20_3 may be magnified by the optical member 1060, and may be provided to the user's right eye through the right eye lens 1020 after the optical path is changed by the optical path changing member 1070. As a result, the user may view an augmented reality image, through the right eye, in which a virtual image displayed on the display device 20_3 and a real image seen through the right eye lens 1020 are combined.

FIG. 12 schematically illustrates that the display device housing 1200_1 is disposed at the right end of the support frame 1030, but the disclosure is not limited thereto. For example, the display device housing 1200_1 may be disposed at the left end of the support frame 1030, and the image of the display device 20_3 may be provided to the user's left eye. In another embodiment, the display device housing 1200_1 may be disposed at both the left and right ends of the support frame 1030, and the user may view the image displayed on the display device 20_3 through both the left and right eyes.

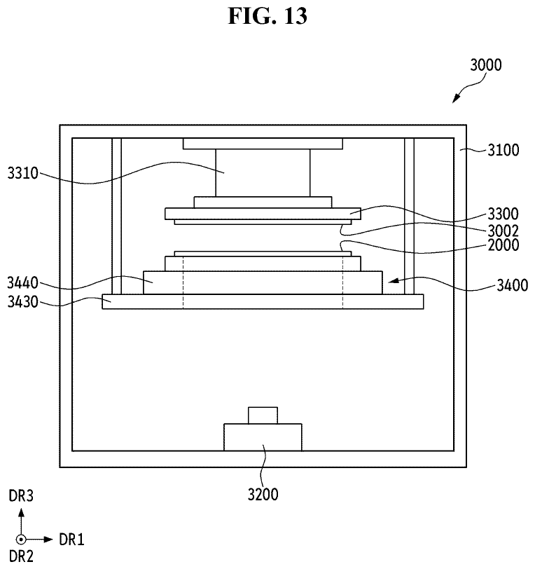

FIG. 13 is a schematic cross-sectional view illustrating a deposition mask and a deposition apparatus including the same according to an embodiment of the disclosure.

Referring to FIG. 13, a deposition apparatus 3000 according to an embodiment of the disclosure may be used for forming light emitting layers on a backplane substrate 3002 for manufacturing a display panel 100 (see FIG. 3). For example, as illustrated in FIG. 9, a semiconductor backplane SBP and a light emitting element backplane EBP may be disposed on the backplane substrate 3002, and a reflective electrode layer RL and an insulating film INS10 may be disposed on the light emitting element backplane EBP. Electrode patterns, e.g., anode electrodes AND, may be disposed on the insulating film INS10, and the anode electrodes AND may be electrically connected to the reflective electrode layer RL through vias VA10. The deposition apparatus 3000 according to an embodiment of the disclosure may be used for forming light emitting stacks ES1, ES2, and ES3 on the anode electrodes AND.

According to an embodiment of the disclosure, the deposition apparatus 3000 may include a deposition source 3200 for providing a deposition material on the backplane substrate 3002, a deposition mask 2000 disposed above the deposition source 3200, and a substrate chuck 3300 that is disposed above the deposition mask 2000 and supports the backplane substrate 3002 such that the backplane substrate 3002 faces the deposition mask 2000. For example, the substrate chuck 3300 may support the backplane substrate 3002 such that a front surface of the backplane substrate 3002 faces the deposition source 3200, and may place the backplane substrate 3002 on the deposition mask 2000 to perform a deposition process.

The deposition source 3200, the deposition mask 2000, and the substrate chuck 3300 may be disposed in a process chamber 3100. The process chamber 3100 may have an internal space, and the deposition process for forming a deposition material layer on the backplane substrate 3002 may be performed in the internal space of the process chamber 3200. Although not shown, the process chamber 3100 may be connected to a vacuum pump (not shown), and a vacuum atmosphere may be created in the internal space of the process chamber 3100 by the vacuum pump. An opening (not shown) for loading/unloading of the backplane substrate 3002 and the deposition mask 2000 may be provided through a sidewall of the process chamber 3100, and the opening may be opened and closed by a gate valve (not shown).

A deposition material may be stored in the deposition source 3200. The deposition source 3200 may evaporate a deposition material, such as an organic material, an inorganic material, a conductive material, or the like, toward the backplane substrate 3002, and the evaporated deposition material may be deposited on the backplane substrate 3002 through the deposition mask 2000. For example, the deposition source 3200 may evaporate an organic material for forming light emitting layers on the backplane substrate 3002, and may be provided with a heater (not shown) for evaporating the organic material. The evaporated organic material may be deposited on electrode patterns on the backplane substrate 3002 through the deposition mask 2000. As shown in FIG. 13, the deposition source 3200 may be disposed on a central portion of a bottom surface of the process chamber 3100. However, the disclosure is not limited thereto, and in another embodiment, the deposition source 3200 may be configured to be movable in a horizontal direction by a separate driver (not shown).

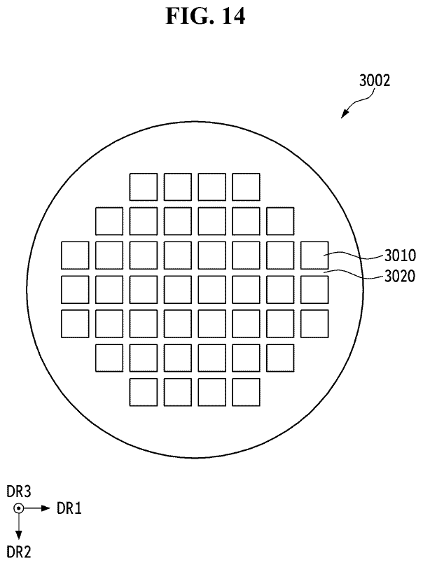

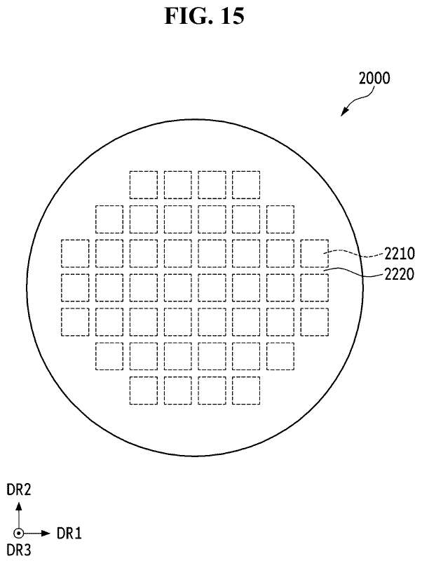

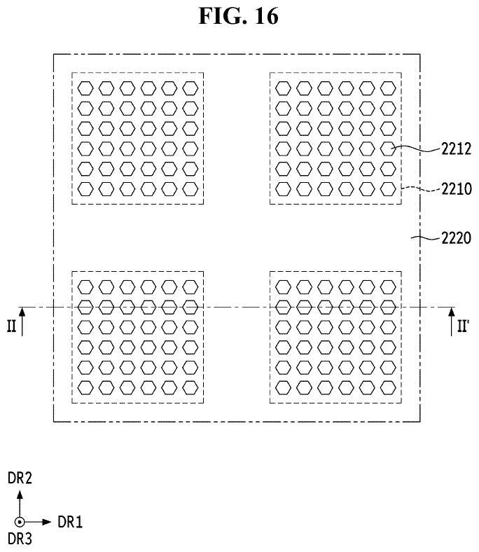

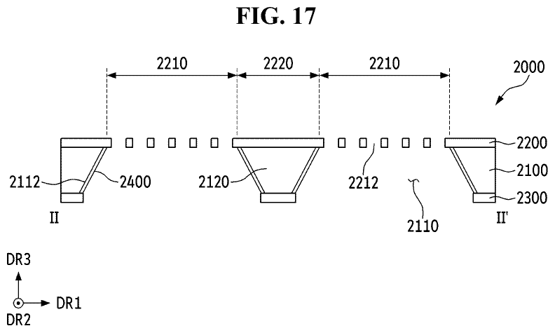

FIG. 14 is a schematic bottom view illustrating the backplane substrate as shown in FIG. 13, and FIG. 15 is a schematic plan view illustrating the deposition mask as shown in FIG. 13. FIG. 16 is a schematic enlarged plan view illustrating mask cell regions as shown in FIG. 15, and FIG. 17 is a schematic cross-sectional view taken along line II-II′ as shown in FIG. 16.

Referring to FIGS. 14 to 17, the backplane substrate 3002 may include multiple display cell regions 3010 and a scribe lane region 3020 disposed between the display cell regions 3010. The display cell regions 3010 may be arranged in a matrix form along a first direction DR1 and a second direction DR2 as illustrated in FIG. 14, and each of the display cell regions 3010 may be individualized into multiple display panels 100 (see FIG. 3) by a dicing process after a display manufacturing process is completed. For example, the first direction DR1 may be a first horizontal direction, and the second direction DR2 may be a second horizontal direction perpendicular to the first direction DR1.

Each of the display cell regions 3010 may include the semiconductor backplane SBP, the light emitting element backplane EBP disposed on the semiconductor backplane SBP, the reflective electrode layer RL disposed on the light emitting element backplane EBP, and the insulating film INS10 disposed on the reflective electrode layer RL. Further, each of the display cell regions 3010 may include multiple electrode patterns, e.g., multiple anode electrodes AND, disposed on the insulating film INS10, and the anode electrodes AND may be connected to the reflective electrode layer RL through multiple vias VA10. The electrode patterns of the display cell regions 3010 may be arranged on the front surface of the backplane substrate 3002, and the substrate chuck 3300 may hold a rear surface of the backplane substrate 3002 such that the electrode patterns of the display cell regions 3010 face downward, for example, face the deposition source 3200.

The deposition mask 2000 may include mask cell regions 2210 respectively corresponding to the display cell regions 3010 of the backplane substrate 3002. Each of the mask cell regions 2210 may have multiple pixel openings 2212 exposing the anode electrodes AND in the deposition process. For example, the deposition mask 2000 may include a mask frame 2100 and a membrane 2200 disposed on the mask frame 2100. The mask frame 2100 may have multiple cell openings 2110 and include a rib region 2120 that defines the cell openings 2110. The membrane 2200 may include mask cell regions 2210 respectively disposed above the cell openings 2110, and a grid region 2220 disposed between the mask cell regions 2210. For example, as illustrated in FIG. 17, the mask cell regions 2210 of the membrane 2200 may be exposed by the cell openings 2110 of the mask frame 2100, and the pixel openings 2212 may penetrate the membrane 2200 and communicate with the cell openings 2110. The grid region 2220 of the membrane 2200 may be disposed on the rib region 2120 of the mask frame 2100.

As shown in FIG. 15, the mask cell regions 2210 may be arranged in a matrix form along the first direction DR1 and the second direction DR2. For example, the mask cell regions 2210 may be arranged in a matrix form along the first horizontal direction DR1 and the second horizontal direction DR2 perpendicular to the first horizontal direction DR1, and may be arranged to respectively correspond to the display cell regions 3010 of the backplane substrate 3002.

The membrane 2200 may be made of an inorganic material such as silicon nitride and may be formed to have a thickness in a range of about 0.5 μm to about 3 μm by a thermal chemical vapor deposition (TCVD) process. The pixel openings 2212 of the membrane 2200 may be formed to correspond to the anode electrodes AND on the backplane substrate 3002. For example, a photoresist pattern (not shown) that exposes portions where the pixel openings 2210 are to be formed may be formed on the membrane 2200, and an anisotropic etching process using the photoresist pattern as an etching mask may be performed to form the pixel openings 2212 penetrating the membrane 2200.

In an embodiment, the membrane 2200 may be disposed on a front surface of the mask frame 2100, and a rear inorganic pattern 2300 may be disposed on a rear surface of the mask frame 2100. The rear inorganic pattern 2300 and the membrane 2200 may be formed simultaneously by the TCVD process, and may be made of a same material. The rear inorganic pattern 2300 may be used as an etching mask in an etching process for forming cell openings 2110. For example, after a rear inorganic layer is formed by the TCVD process, a photoresist pattern may be formed on the rear inorganic layer, and an anisotropic etching process using the photoresist pattern as an etching mask may be performed to form the rear inorganic pattern 2300 on the rear surface of the mask frame 2100.

The cell openings 2110 of the mask frame 2100 may be formed such that the mask cell regions 2210 of the membrane 2200 are exposed by an anisotropic etching process using the rear inorganic pattern 2300 as an etching mask. For example, a single crystal silicon substrate may be used as the mask frame 2100, and the cell openings 2110 may be formed by a wet etching process using tetramethyl ammonium hydroxide (TMAH), potassium hydroxide (KOH), or the like. For example, the <100> crystal direction of the single crystal silicon substrate used as the mask frame 2100 may be the third direction DR3, so that the cell openings 2110 may be formed to have a width that gradually decreases toward the membrane 2200, i.e., in the third direction DR3, by the wet etching process. Each of inner surfaces 2112 of the cell openings 2110 may be formed to have an inclination of about 54.74° with respect to the rear surface of the mask frame 2100.

According to an embodiment of the disclosure, reflective patterns 2400 that reflect thermal radiation energy may be arranged on the inner surfaces 2112 of the cell openings 2110. The reflective patterns 2400 may reflect thermal radiation energy radiated from the deposition source 3200, so that the temperature of the deposition mask 2000 may be prevented from being excessively increased by the thermal radiation energy from the deposition source 3200. As a result, the temperature of the deposition mask 2000 may be lowered compared to a conventional technique while the deposition process is being performed, thereby reducing the thermal expansion of the deposition mask 2000, and improving the pixel position accuracy (PPA) of the deposition material layers formed on the backplane substrate 3002.

The reflective patterns 2400 may be made of a metal or a metal oxide, and may have a thickness in a range of about 10 nm to about 100 nm on the inner surfaces 2112 of the cell openings 2110. For example, the reflective patterns 2400 may include a metal such as aluminum (Al), titanium (Ti), magnesium (Mg), zinc (Zn), cerium (Ce), tantalum (Ta), tungsten (W), molybdenum (Mo), chromium (Cr), nickel (Ni), ruthenium (Ru), palladium (Pd), platinum (Pt), gold (Au), silver (Ag), or copper (Cu). In another embodiment, the reflective patterns 2400 may include a metal oxide such as aluminum oxide (Al₂O₃), titanium oxide (TiO₂), magnesium oxide (MgO), zinc oxide (ZnO), or cerium oxide (CeO₂).

For example, a reflective pattern, i.e., a metal layer or a metal oxide layer, may not be formed on the membrane 2200. For example, in case that a metal layer or a metal oxide layer is formed on the mask cell regions 2210 exposed through the cell openings 2110, deformation such as cell warpage may occur in the mask cell regions 2210 due to residual stress of the metal layer or the metal oxide layer, and the size of the pixel openings 2212 may be reduced by the metal layer or the metal oxide layer. Therefore, the reflective patterns 2400 may be formed only on the inner surfaces 2112 of the cell openings 2110.

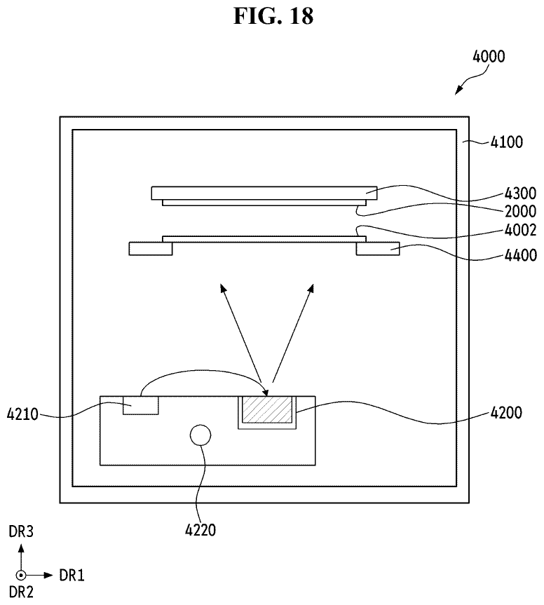

FIG. 18 is a schematic cross-sectional view illustrating a method of forming the reflective patterns as illustrated in FIG. 17.

Referring to FIG. 18, the reflective patterns 2400 may be formed by a physical vapor deposition process. For example, the reflective patterns 2400 may be formed by an electron beam (E-beam) evaporation process using a shadow mask 4002 that exposes the inner surfaces 2112 of the cell openings 2110. An E-beam evaporator 4000 for performing the E-beam evaporation process may include a vacuum chamber 4100, a crucible 4200 that is disposed in the vacuum chamber 4100 and accommodates an evaporation source such as a metal or a metal oxide, a substrate holder 4300 that is disposed above the crucible 4200 and supports the deposition mask 2000, a mask stage 4400 that supports the shadow mask 4002, or the like.

An electron gun 4210 for providing an electron beam may be disposed on a side of the crucible 4200, and a permanent magnet 4220 or an electromagnet may be disposed between the crucible 4200 and the electron gun 4210 to guide the electron beam irradiated from the electron gun 4210 to the evaporation source using a magnetic field. The evaporation source accommodated in the crucible 4200 may be heated and melted by the electron beam, and a material evaporated from the evaporation source may move upward and be deposited on the deposition mask 2000. For example, the substrate holder 4300 may hold the deposition mask 2000 such that the rear surface of the deposition mask 2000 faces downward, and the shadow mask 4002 that exposes the inner surfaces 2112 of the cell openings 2110 may be disposed below the substrate holder 4300. Metal or metal oxide particles evaporated from the evaporation source may be deposited on the inner surfaces 2112 of the cell openings 2110 by the shadow mask 4002, so that the reflective patterns 2400 made of a metal or a metal oxide may be formed on the inner surfaces 2112 of the cell openings 2110. An embodiment of the configuration of the E-beam evaporator 4000 for forming the reflective patterns 2400 has been described, but the disclosure is not limited thereto, and the configuration of the E-beam evaporator 4000 may be variously changed.

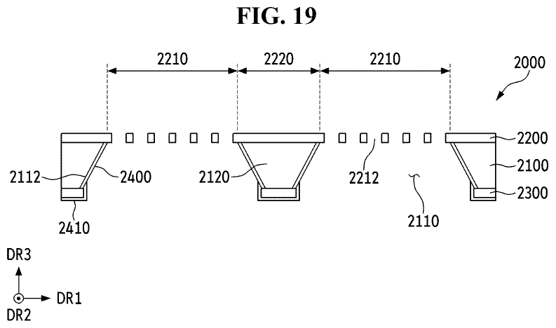

FIG. 19 is a schematic cross-sectional view illustrating another embodiment of the deposition mask shown in FIG. 17.

Referring to FIG. 19, a reflective layer 2410 may be formed on the rear surface of the mask frame 2100. The reflective layer 2410 and the reflective patterns 2400 may be made of a same material For example, the reflective layer 2410 may be formed on the rear inorganic pattern 2300, and may be formed simultaneously with the reflective patterns 2400 by an E-beam evaporation process. A shadow mask that exposes the inner surfaces 2112 of the cell openings 2110 and the rear inorganic pattern 2300 may be used in the E-beam evaporation process.

Referring back to FIG. 13, the substrate chuck 3300 may be disposed above the deposition source 3200 and may support the backplane substrate 3002 such that the backplane substrate 3002 faces the deposition source 3200. For example, the substrate chuck 3300 may be an electrostatic chuck that holds the rear surface of the backplane substrate 3002 using an electrostatic force. For example, the electrode patterns, i.e., the anode patterns AND, may be arranged on the front surface of the backplane substrate 3002, and the substrate chuck 3300 may hold the rear surface of the backplane substrate 3002 such that the front surface of the backplane substrate 3002 faces the deposition source, i.e., faces downward.

Although not shown, the backplane substrate 3002 may be transferred into the process chamber 3100 by a transfer robot (not shown), and lift fingers (not shown) for transferring the backplane substrate 3002 from the transfer robot to the substrate chuck 3300 may be disposed in the process chamber 3100. For example, the backplane substrate 3002 may be transferred into the process chamber 3100 and placed on the lift fingers by the transfer robot, and the lift fingers may be raised to load the backplane substrate 3002 onto the substrate chuck 3300. The substrate chuck 3300 may hold the rear surface of the backplane substrate 3002 using an electrostatic force.

A mask stage 3400 on which the deposition mask 2000 is placed may be disposed above the deposition source 3200. For example, the mask stage 3400 may be disposed under the substrate chuck 3300, and may support an edge portion of the deposition mask 2000. The deposition mask 2000 may be transferred into the process chamber 3100 by a transfer robot (not shown). For example, the deposition mask 2000 transferred into the process chamber 3100 by the transfer robot may be placed on the lift fingers, and the lift fingers may be lowered to load the deposition mask 2000 onto the mask stage 3400.

An upper driver 3310 for moving and rotating the substrate chuck 3300 may be disposed above the substrate chuck 3300 to adjust the position and angle of the backplane substrate 3002. For example, the upper driver 3310 may move the substrate chuck 3300 in the first direction DR1 and the second direction DR2 to adjust the horizontal position of the backplane substrate 3002, and may move the substrate chuck 3300 in the third direction DR3 to adjust the vertical position of the backplane substrate 3002. The first direction DR1, the second direction DR2, and the third direction DR3 may be the X-axis direction, the Y-axis direction, and the Z-axis direction, respectively.

Further, the upper driver 3310 may rotate the substrate chuck 3300 around the Z-axis to adjust the azimuth of the backplane substrate 3002. Further, in order to adjust the inclination of the backplane substrate 3002, the upper driver 3310 may rotate the substrate chuck 3300 around the X-axis, and may rotate the substrate chuck 3300 around the Y-axis. For example, the upper driver 3310 may include a hexapod actuator that provides six degrees of freedom (X, Y, Z, θx, θy, and θz) motion.

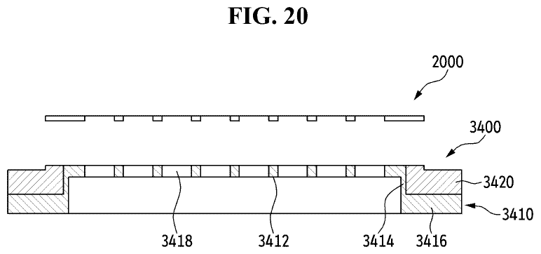

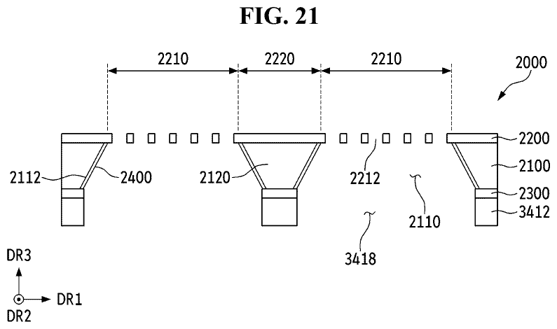

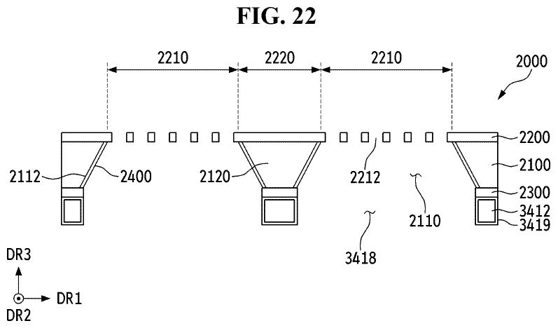

FIG. 20 is a schematic cross-sectional view illustrating the mask stage as shown in FIG. 13. FIG. 21 is a schematic enlarged cross-sectional view illustrating a lattice support as shown in FIG. 20. FIG. 22 is a schematic enlarged cross-sectional view illustrating another embodiment of the lattice support as shown in FIG. 20.

Referring to FIGS. 13, 20, and 21, the mask stage 3400 may include a lattice support 3410 for supporting the rib region 2120 of the mask frame 2100, and a mask chuck 3420 having a ring shape surrounding the lattice support 3410 in a plan view and supporting an edge portion of the mask frame 2100. The lattice support 3410 may include a lattice plate 3412 for supporting the rib region 2120 of the mask frame 2100, and a support ring 3414 extending downward from an edge portion of the lattice plate 3412. For example, the lattice plate 3412 may have a disc shape, and the support ring 3414 may have a circular ring shape in a plan view. Further, the lattice support 3410 may include a flange 3416 surrounding a lower portion of the support ring 3414 in a plan view. The mask chuck 3420 may be disposed on the flange 3416, and may have a circular ring shape surrounding the support ring 3414 in a plan view. For example, the mask chuck 3420 may be an electrostatic chuck, and may hold the edge portion of the deposition mask 2000 using an electrostatic force.

The mask stage 3400 may include a support plate 3430 for supporting the lattice support 3410 and the mask chuck 3420. The support plate 3430 may have an opening so that the mask cell regions 2210 of the deposition mask 2000 are exposed toward the deposition source 3200, and a lower driver 3440 for adjusting the position and angle of the deposition mask 2000 may be disposed between the support plate 3430 and the flange 3416. For example, the lower driver 3440 may move the lattice support 3410 and the mask chuck 3420 in the first direction DR1 and the second direction DR2 to adjust the horizontal position of the deposition mask 2000, and may rotate the lattice support 3410 and the mask chuck 3420 around the Z-axis to adjust the azimuth of the deposition mask 2000. For example, the lower driver 3440 may include a piezo actuator that provides three degrees of freedom (X, Y, and θz) motion, and the piezo actuator may have a square ring shape.

According to an embodiment of the disclosure, the lattice support 3410 may have lattice holes 3418 respectively corresponding to the cell openings 2110 of the deposition mask 2000, and the lattice support 3410 and the reflective patterns 2400 of the deposition mask 2000 may be made of a same material to reflect thermal radiation energy from the deposition source 3200.

In another embodiment, referring to FIG. 22, the mask stage 3400 may further include a coating layer 3419 disposed on the lattice support 3410. The lattice support 3410 may be made of a metal such as stainless steel, and the coating layer 3419 and the reflective patterns 2400 of the deposition mask 2000 may be made of a same material to reflect thermal radiation energy from the deposition source 3200. For example, the lattice support 3410 may be made of a precipitation hardening stainless steel such as A 694 and A 693, and the coating layer 3419 may be made of a metal such as aluminum (Al), titanium (Ti), magnesium (Mg), zinc (Zn), cerium (Ce), tantalum (Ta), tungsten (W), molybdenum (Mo), chromium (Cr), nickel (Ni), ruthenium (Ru), palladium (Pd), platinum (Pt), gold (Au), silver (Ag), or copper (Cu), or a metal oxide such as aluminum oxide (Al₂O₃), titanium oxide (TiO₂), magnesium oxide (MgO), zinc oxide (ZnO), or cerium oxide (CeO₂).

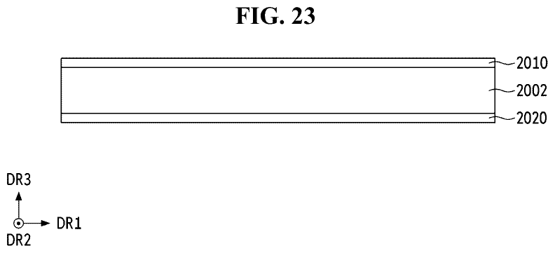

FIGS. 23 to 29 are schematic cross-sectional views illustrating a method of manufacturing a deposition mask according to an embodiment of the disclosure.

Referring to FIG. 23, an inorganic layer 2010 may be formed on a mask substrate 2002. For example, a single crystal silicon substrate may be used as the mask substrate 2002, and the mask substrate 2002 may function as a mask frame 2100 of the deposition mask 2000. The inorganic layer 2010 may be formed to have a thickness in a range of about 0.5 μm to about 3 μm on the mask substrate 2002 by a TCVD process, and may function as a membrane 2200 of the deposition mask 2000.

The inorganic layer 2010 may include silicon nitride, and a first source gas containing silicon and a second source gas containing nitrogen may be supplied into a process chamber of a deposition apparatus for performing the TCVD process. For example, dichlorosilane (DCS) (SiH₂Cl₂) gas may be used as the first source gas, ammonia (NH₃) gas may be used as the second source gas, and the inorganic layer 2010 may be formed by the reaction between the first source gas and the second source gas. The inorganic layer 2010 may be formed on a front surface of the mask substrate 2002, and a rear inorganic layer 2020 may be formed on a rear surface of the mask substrate 2002. For example, the inorganic layer 2010 and the rear inorganic layer 2020 may be formed simultaneously by the TCVD process, and the inorganic layer 2010 and the rear inorganic layer 2020 may be made of a same material.

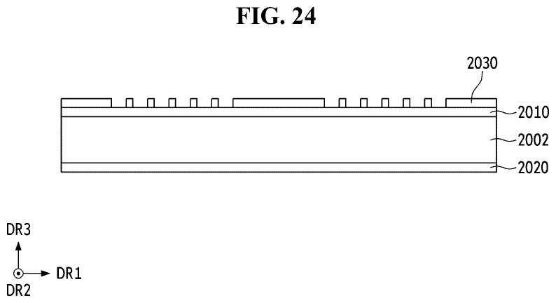

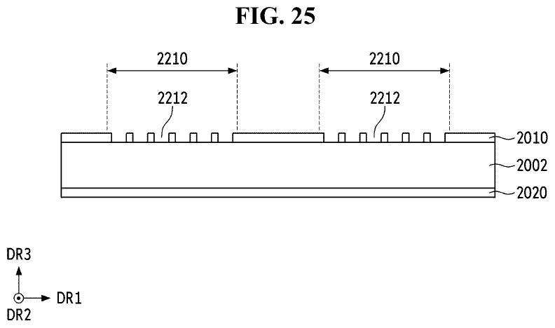

Referring to FIGS. 24 and 25, the inorganic layer 2010 may be patterned to form mask cell regions 2210, each having multiple pixel openings 2212 that expose the mask substrate 2002. For example, as illustrated in FIG. 24, after a first photoresist pattern 2030 that exposes portions where the pixel openings 2212 are to be formed is formed on the inorganic layer 2010, an etching process using the first photoresist pattern 2030 as an etching mask may be performed to form the pixel openings 2212 that expose the mask substrate 2002, as illustrated in FIG. 25. For example, the pixel openings 2212 may be formed by a reactive ion etching (RIE) process using a reaction gas such as CHF₃, CH₃F, CH₂F₂, CHF₆, CF₄, C₂F₆, C₃F₆, or the like and a sputtering gas such as Ar, O₂/Ar, or the like. An inductively coupled plasma (ICP) source or a capacitively coupled plasma (CCP) source may be used as a plasma source. For example, by appropriately controlling the flow rates of the reaction gas and the sputtering gas, the internal temperature of the process chamber, the RF power for plasma generation, the bias power applied to a chuck on which the mask substrate 2002 is placed, or the like, the pixel openings 2212 may be made to have a constant width in the thickness direction of the inorganic layer 2010. The first photoresist pattern 2030 may be removed by a stripping and/or ashing process after the pixel openings 2212 are formed.

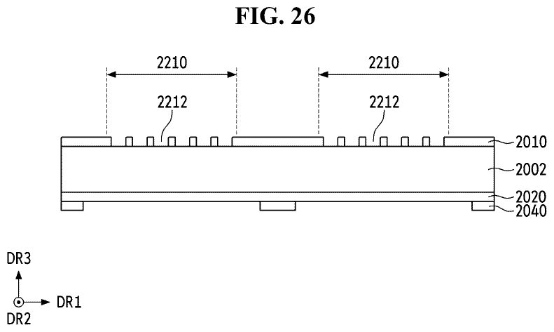

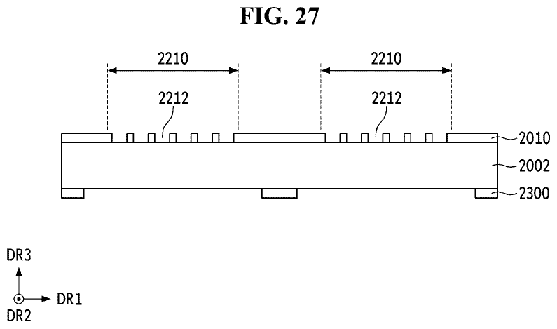

Referring to FIGS. 26 to 28, the mask substrate 2002 may be patterned to form the cell openings 2110 that respectively expose the mask cell regions 2210. The pixel openings 2212 may communicate with the cell openings 2110. For example, as illustrated in FIG. 26, after a second photoresist pattern 2040 that exposes portions where the cell openings 2110 are to be formed is formed on the rear inorganic layer 2020, an anisotropic etching process, e.g., an RIE process, using the second photoresist pattern 2040 as an etching mask may be performed, thereby forming the rear inorganic pattern 2300 on the rear surface of the mask substrate 2002, as illustrated in FIG. 27. The second photoresist pattern 2040 may be removed by a stripping and/or ashing process after the rear inorganic pattern 2300 is formed.

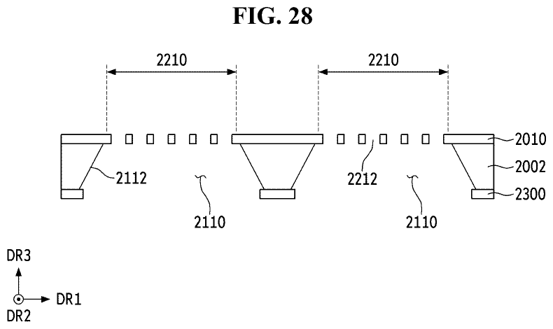

As illustrated in FIG. 28, the mask substrate 2002 may be partially removed to expose the pixel openings 2212 by a wet etching process using the rear inorganic pattern 2300 as an etching mask, so that the cell openings 2110 that respectively expose the mask cell regions 2210 may be formed. For example, the wet etching process may be performed using an etching solution including tetramethyl ammonium hydroxide (TMAH) or potassium hydroxide (KOH). For example, the <100> crystal direction of the single crystal silicon substrate used as the mask substrate 2002 may be the third direction DR3, so that the cell openings 2110 may be formed to have a width that gradually decreases toward the inorganic layer 2010, i.e., in the third direction DR3, by the wet etching process. For example, each of inner surfaces 2112 of the cell openings 2110 may be formed to have an inclination of about 54.74° with respect to the rear surface of the mask substrate 2002.

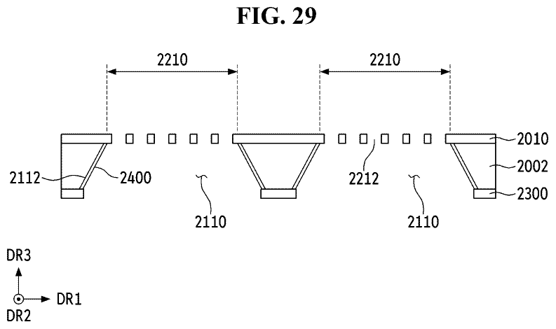

Referring to FIG. 29, the reflective patterns 2400 made of a material that reflects thermal radiation energy may be formed on the inner surfaces 2112 of the cell openings 2110. For example, the reflective patterns 2400 may be made of a metal such as aluminum (Al), titanium (Ti), magnesium (Mg), zinc (Zn), cerium (Ce), tantalum (Ta), tungsten (W), molybdenum (Mo), chromium (Cr), nickel (Ni), ruthenium (Ru), palladium (Pd), platinum (Pt), gold (Au), silver (Ag), or copper (Cu), or a metal oxide such as aluminum oxide (Al₂O₃), titanium oxide (TiO₂), magnesium oxide (MgO), zinc oxide (ZnO), or cerium oxide (CeO₂).

The reflective patterns 2400 may be formed to have a thickness in a range of about 10 nm to about 100 nm on the inner surfaces 2112 of the cell openings 2110 by an E-beam evaporation process. For example, the shadow mask 4002 (see FIG. 28) that exposes the inner surfaces 2112 of the cell openings 2110 may be used while the E-beam evaporation process is being performed, and the reflective patterns 2400 may be selectively formed on the inner surfaces 2112 of the cell openings 2110 by the shadow mask 4200. For example, while the E-beam evaporation process is being performed, a metal layer or a metal oxide layer may not be formed on the mask cell regions 2210 of the inorganic layer 2010 by the shadow mask 4002, and a metal layer or a metal oxide layer functioning as the reflective patterns 2400 may be selectively formed only on the inner surfaces 2112 of the cell openings 2110.

In another embodiment, as illustrated in FIG. 19, a reflective layer 2410 made of a same material as the reflective patterns 2400 may be formed on the rear surface of the mask substrate 2002. For example, the reflective layer 2410 may be formed on the rear inorganic pattern 2300, and may be formed simultaneously with the reflective patterns 2400 by the E-beam evaporation process. A shadow mask that exposes the inner surfaces of the cell openings 2110 and the rear inorganic pattern 2300 may be used in the E-beam evaporation process.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A deposition mask comprising:
a mask frame having cell openings and comprising a rib region defining the cell openings;
a membrane comprising mask cell regions each disposed on the cell openings; and
reflective patterns disposed on inner surfaces of the cell openings and reflecting thermal radiation energy.

2. The deposition mask of claim 1, wherein the reflective patterns are made of a metal or a metal oxide.

3. The deposition mask of claim 2, wherein the reflective patterns comprise at least one of aluminum (Al), titanium (Ti), magnesium (Mg), zinc (Zn), cerium (Ce), tantalum (Ta), tungsten (W), molybdenum (Mo), chromium (Cr), nickel (Ni), ruthenium (Ru), palladium (Pd), platinum (Pt), gold (Au), silver (Ag), and copper (Cu).

4. The deposition mask of claim 2, wherein the reflective patterns comprise at least one of aluminum oxide (Al₂O₃), titanium oxide (TiO₂), magnesium oxide (MgO), zinc oxide (ZnO), and cerium oxide (CeO₂).

5. The deposition mask of claim 1, wherein each of the inner surfaces of the cell openings has an inclination such that the cell openings have a width that gradually decreases toward the membrane.

6. The deposition mask of claim 1, wherein the reflective patterns have a thickness in a range of about 10 nm to about 100 nm.

7. The deposition mask of claim 1, further comprising:
a reflective layer, wherein
the membrane is disposed on a front surface of the mask frame,
the reflective layer is disposed on a rear surface of the mask frame, and
the reflective layer and the reflective patterns are made of a same material.

8. A deposition apparatus comprising:
a deposition source;
a deposition mask disposed above the deposition source; and
a substrate chuck supporting a substrate such that the substrate faces the deposition mask,
wherein the deposition mask comprises:
a mask frame having cell openings and comprising a rib region defining the cell openings;
a membrane comprising mask cell regions each disposed on the cell openings; and
reflective patterns disposed on inner surfaces of the cell openings and reflecting thermal radiation energy.

9. The deposition apparatus of claim 8, wherein the reflective patterns are made of a metal or a metal oxide.

10. The deposition apparatus of claim 8, wherein each of the inner surfaces of the cell openings has an inclination such that the cell openings have a width that gradually decreases toward the membrane.

11. The deposition apparatus of claim 8, wherein
the deposition mask further comprises a reflective layer,
the membrane is disposed on a front surface of the mask frame,
the reflective layer is disposed on a rear surface of the mask frame, and
the reflective layer and the reflective patterns are made of a same material.

12. The deposition apparatus of claim 8, further comprising:
a mask stage which is disposed above the deposition source and on which the deposition mask is placed,
wherein the mask stage comprises:
a lattice support supporting the rib region of the mask frame; and
a mask chuck having a ring shape surrounding the lattice support in a plan view and supporting an edge portion of the mask frame.

13. The deposition apparatus of claim 12, wherein the lattice support and the reflective patterns are made of a same material.

14. The deposition apparatus of claim 12, wherein
the mask stage further comprises a coating layer disposed on the lattice support, and
the coating layer and the reflective patterns are made of a same material.

15. A method of manufacturing a deposition mask, comprising:
forming an inorganic layer on a substrate;
patterning the inorganic layer to form mask cell regions each having a plurality of pixel openings exposing the substrate;
patterning the substrate to form cell openings each exposing the mask cell regions; and
forming reflective patterns made of a material reflecting thermal radiation energy on inner surfaces of the cell openings.

16. The method of claim 15, wherein the reflective patterns are made of a metal or a metal oxide.

17. The method of claim 15, wherein
the substrate is a single crystal silicon substrate, and
the cell openings are formed by a wet etching process to have a width that gradually decreases toward the inorganic layer.

18. The method of claim 17, wherein the reflective patterns are formed by an electron beam evaporation process using a shadow mask that exposes the inner surfaces of the cell openings.

19. The method of claim 15, further comprising:
forming a reflective layer on a rear surface of the substrate, wherein
the inorganic layer is formed on a front surface of the substrate, and
the reflective layer and the reflective patterns are made of a same material and formed simultaneously.

20. An electronic device comprising:
a display panel comprising a substrate and light emitting layers formed on the substrate using a deposition mask that comprises:
a mask frame having cell openings and comprising a rib region defining the cell openings;
a membrane comprising mask cell regions each disposed on the cell openings; and
reflective patterns disposed on inner surfaces of the cell openings and reflecting thermal radiation energy.
